(19) United States
(12) Patent Application Publication
(10) Pub. No.: US 2025/0219040 A1
(43) Pub. Date: Jul. 3, 2025

(54) Technologies for Components Embedded in a Substrate Core

(71) Applicant: Intel Corporation, Santa Clara, CA (US)

(72) Inventors: Tolga ACIKALIN, San Jose, CA (US); Soham AGARWAL, Chandler, AZ (US); Benjamin T. DUONG, Phoenix, AZ (US); Jeremy D. ECTON, Gilbert, AZ (US); Kari E. HERNANDEZ, Phoenix, AZ (US); Brandon Christian MARIN, Gilbert, AZ (US); Pratyush MISHRA, Tempe, AZ (US); Pratyasha MOHAPATRA, Hillsboro, OR (US); Srinivas Venkata Ramanuja PIETAMBARAM, Chandler, AZ (US); Marcel M. SAID, Beaverton, OR (US); Suddhasattwa NAD, Chandler, AZ (US); Gang DUAN, Chandler, AZ (US); Zhixin XIE, Chandler, AZ (US); Jung Kyu HAN, Chandler, AZ (US); Mohamed R. SABER, College Station, TX (US); Shuren QU, Gilbert, AZ (US); Naiya SOETAN-DODD, Mesa, AZ (US); Teng SUN, Chandler, AZ (US); Yuxin FANG, Chandler, AZ (US)

(21) Appl. No.: 18/399,255

(22) Filed: Dec. 28, 2023

(51) Int. Cl. H01L 25/18; H01L 23/00; H01L 23/498; H01L 23/538; H01L 23/64; H01L 29/66; H01L 29/94

(52) U.S. Cl. CPC H01L 25/18; H01L 23/49827; H01L 23/5384; H01L 23/645; H01L 24/16; H01L 24/32; H10D 1/047; H10D 1/665; H01L 2224/16235; H01L 2224/32145; H01L 2924/1205; H01L 2924/1206

(57) ABSTRACT

Technologies for components embedded in a substrate core are disclosed. In one embodiment, power components such as deep trench capacitors are disposed in a cavity defined in a substrate core for a circuit board of an integrated circuit package, such as a processor. The power components are stacked on top of each other, allowing for the stack of power components to match the height of the substrate core, even when the height of the individual power components is less than the height of the substrate core. Configuring the power components in this manner can provide mechanical stability to the power components and substrate core and provide power to a semiconductor die mounted on the circuit board.

### BACKGROUND

High-power semiconductor dies require a large amount of current at a stable voltage. In order to provide a stable voltage, capacitors are often placed near the dies, such as on the same package as the dies. Capacitors near the dies can suppress power delivery noise and improve power delivery performance. Deep trench capacitors can be used as some of the capacitors to provide more stable power. In a deep trench capacitor, a three-dimensional vertical capacitor is formed by etching deep trenches in a silicon substrate.

### BRIEF DESCRIPTION OF THE DRAWINGS

FIG. 1 is an isometric view of one embodiment of a system with an integrated circuit component on a circuit board with power components embedded in a substrate core.

FIG. 2 is a cross-sectional view of the system of FIG. 1.

FIGS. 3 and 4 are a flowchart of one embodiment of a method of creating one embodiment of the system of FIG. 1.

FIG. 5 is a cross-sectional view of one embodiment of a wafer for deep trench capacitors at one stage of the flowchart of FIGS. 3 and 4.

FIG. 6 is a cross-sectional view of one embodiment of a wafer for deep trench capacitors at one stage of the flowchart of FIGS. 3 and 4.

FIG. 7 is a cross-sectional view of one embodiment of a wafer for deep trench capacitors at one stage of the flowchart of FIGS. 3 and 4.

FIG. 8 is a cross-sectional view of one embodiment of a system at one stage of the flowchart of FIGS. 3 and 4.

FIG. 9 is a cross-sectional view of one embodiment of a system at one stage of the flowchart of FIGS. 3 and 4.

FIG. 10 is a cross-sectional view of one embodiment of a system at one stage of the flowchart of FIGS. 3 and 4.

FIG. 11 is a cross-sectional view of one embodiment of a system at one stage of the flowchart of FIGS. 3 and 4.

FIG. 12 is a cross-sectional view of one embodiment of a system at one stage of the flowchart of FIGS. 3 and 4.

FIG. 13 is a cross-sectional view of one embodiment of a system at one stage of the flowchart of FIGS. 3 and 4.

FIG. 14 is a cross-sectional view of one embodiment of a system at one stage of the flowchart of FIGS. 3 and 4.

FIG. 15 is a cross-sectional view of one embodiment of a system at one stage of the flowchart of FIGS. 3 and 4.

FIG. 16 is a cross-sectional view of one embodiment of a system at one stage of the flowchart of FIGS. 3 and 4.

FIG. 17 is a cross-sectional view of one embodiment of a system at one stage of the flowchart of FIGS. 3 and 4.

FIG. 18 is a partial flowchart of one embodiment of a method of creating one embodiment of the system of FIG. 1.

FIG. 19 is a cross-sectional view of one embodiment of a system at one stage of the flowchart of FIG. 18.

FIG. 20 is a cross-sectional view of one embodiment of a system at one stage of the flowchart of FIG. 18.

FIG. 21 is a cross-sectional view of one embodiment of a system at one stage of the flowchart of FIG. 18.

FIG. 22 is a cross-sectional view of one embodiment of a system at one stage of the flowchart of FIG. 18.

FIG. 23 is a cross-sectional view of one embodiment of a variation of the system of FIG. 1.

FIG. 24 is a cross-sectional view of one embodiment of a variation of the system of FIG. 1.

FIG. 25 is a cross-sectional view of one embodiment of a variation of the system of FIG. 1.

FIG. 26 is a cross-sectional view of one embodiment of a variation of the system of FIG. 1.

FIG. 27 is a cross-sectional view of one embodiment of a variation of the system of FIG. 1.

FIG. 28 is a cross-sectional view of one embodiment of a variation of the system of FIG. 1.

FIG. 29 is a cross-sectional view of one embodiment of a variation of the system of FIG. 1.

FIG. 30 is a top view of a wafer and dies that may be included in a microelectronic assembly, in accordance with any of the embodiments disclosed herein.

FIG. 31 is a cross-sectional side view of an integrated circuit device that may be included in a microelectronic assembly, in accordance with any of the embodiments disclosed herein.

FIGS. 32A-32D are perspective views of example planar, gate-all-around, and stacked gate-all-around transistors.

FIG. 33 is a cross-sectional side view of an integrated circuit device assembly that may include a microelectronic assembly, in accordance with any of the embodiments disclosed herein.

FIG. 34 is a block diagram of an example electrical device that may include a microelectronic assembly, in accordance with any of the embodiments disclosed herein.

### DETAILED DESCRIPTION

In various embodiments disclosed herein, an integrated circuit component has a circuit board with a semiconductor die disposed on its surface. The circuit board has a substrate core with a cavity defined in it. Power components, such as deep trench capacitors (DTCs), may be embedded within the cavity of the substrate core. The DTCs can provide improved power and voltage for the semiconductor die. Embedding several DTCs in the substrate core can provide several advantages, such as reducing real estate otherwise occupied by the DTCs and providing a short power delivery path to the semiconductor die.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

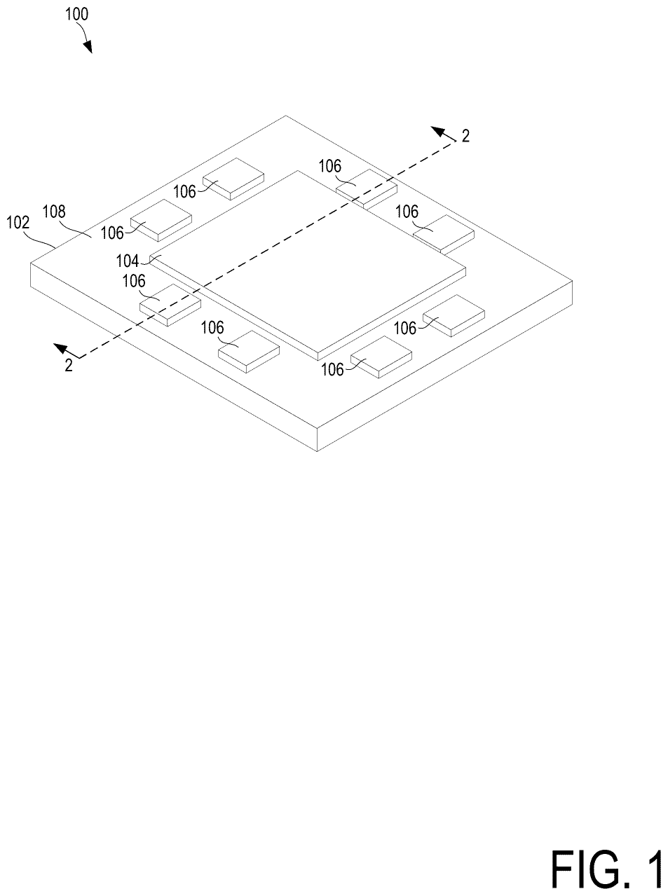

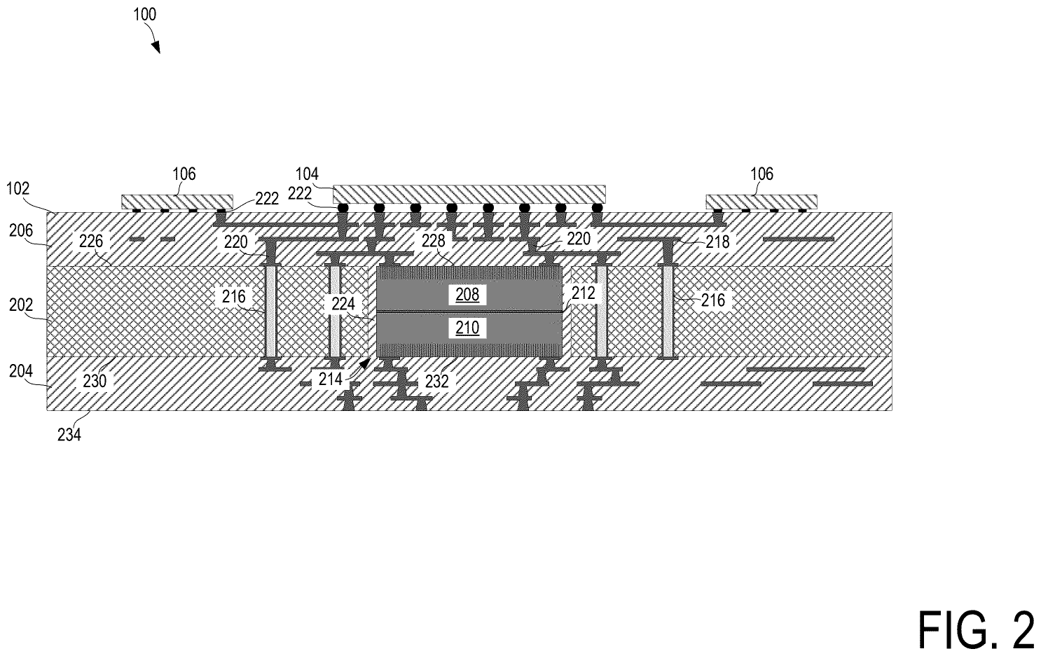

Referring now to FIGS. 1 and 2, in one embodiment, an integrated circuit component 100 includes a circuit board 102 on which one or more dies 104 are mounted. FIG. 1 shows an isometric view of the integrated circuit component 100, and FIG. 2 shows a cross-sectional view of the integrated circuit component 100. As shown in FIG. 1, a die 104 such as a processor die 104 may be disposed on the top surface 108 of the circuit board 102. In an illustrative embodiment, additional components 106, such as other semiconductor dies 106, are disposed on the top surface 108 of the circuit board 102 as well.

It should be appreciated that, as used herein, the “top side,” “bottom side,” etc., is an arbitrary designation used for clarity and does not denote a particular required orientation for manufacture or use. Although the illustrative embodiment described has the components 104, 106 placed on the “top” side of the circuit board 102, in some embodiments, those components may be placed on the “bottom” side of the circuit board 102.

The circuit board 102 includes a substrate core 202, lower build-up layers 204, and upper build-up layers 206. A cavity 214 is defined in the substrate core 202. Power components 208, 210 are disposed within the cavity 214. Upper power component 208 is disposed above the lower power component 210. In an illustrative embodiment, a top surface 228 of the upper power component 208 is approximately in a plane defined by a top surface 226 of the substrate core 202, and a bottom surface 232 of the lower power component 210 is approximately in a plane defined by a bottom surface 230 of the substrate core 202. For example, the top surface 228 of the upper power component 208 may be within 0-500 micrometers of the plane defined by top surface 226 of the substrate core 202. In an illustrative embodiment, the top surface 228 of the upper power component 208 may be within, e.g., 20 micrometers of the plane defined by the top surface 226 of the substrate core 202. The bottom surface 232 of the lower power component 210 may be similarly positioned relative to the plane defined by the bottom surface 230 of the substrate core 202.

The power components 208, 210 may be any suitable power components. For example, in an illustrative embodiment, the power components 208, 210 are DTCs. Additionally or alternatively, in some embodiments, one or both of the power components 208, 210 may be another power component, such as a magnetic inductor array 208, 210. The DTCs 208, 210 may each include one or more separate capacitors. The DTCs 208, 210 may have any suitable capacitance, such as a capacitance of 1 femtofarad-10 microfarad and/or a capacitance density of 0.01-100 nanofarad per square millimeter. The DTCs 208, 210 may have the same capacitance or different capacitance. In some embodiments, the DTCs 208, 210 may be manufactured using different silicon nodes. The DTCs 208, 210 may contain one capacitor each, or one or both may contain more than one capacitor each, such as 2-1,024. The power components 208, 210 may form part of or be connected to a voltage regulator, such as a fully-integrated voltage regulator (FIVR).

The power components 208, 210 in the cavity 214 of the substrate core 202 may provide a range of possible advantages in various embodiments. For example, the power components 208, 210 may otherwise be disposed on the bottom surface 234 of the circuit board 102, taking up real estate that can instead be used for signal routing, input/output pads, solder balls, land grid array, etc. The bottom surface 234 of the circuit board 102 may also be referred to as the land side or back side of the circuit board 102. The power components 208, 210 can be directly under a semiconductor die 104 they provide power to, reducing the path length between the power components 208, 210 and the semiconductor die 104.

Additionally, stacking the power components 208, 210 can provide advantages compared to positioning a single power component 208, 210 in the substrate core 202. In some cases, a height of a power component 208 may be limited to, e.g., 650 micrometers, while the substrate core 202 may be taller, such as 1 millimeter. A single power component 208 disposed in a cavity 214 of the substrate core 202 may leave vertical space in the cavity 214 that would need to be filled with, e.g., mold or other filler. The mold or other filler may cause structural or mechanical issues, such as shifting of the power component 208 or other components due to, e.g., mismatch of coefficient of thermal expansion. With two power components 208, 210, however, the thickness of the power components 208, 210 can be reduced to, e.g., 500 millimeters, so that the total height of the power components 208, 210 in the cavity 214 match the height of the substrate core 202.

In an illustrative embodiment, the circuit board 102 is a multi-layer circuit board 102 with build-up layers 204, 206 above and below the substrate core 202. The build-up layers 204, 206 may have any suitable number of layers, such as 1-10 layers each. In other embodiments, the circuit board 102 may be a single-layer circuit board 102. In an illustrative embodiment, the substrate core 202 may be an organic core, such as a fiberglass board made of glass fibers and a resin, such as FR-4. In some embodiments, the substrate core 202 may be an inorganic core 202, such as a glass core 202. The glass core 202 may be silicon oxide glass. In other embodiments, the glass core 202 may be made of any suitable material that may be crystalline, non-crystalline, amorphous, etc., such as fused silicon, borosilicate, sapphire, yttrium aluminum garnet, etc. The glass core 202 may be, e.g., aluminosilicate glass, borosilicate glass, alumino-borosilicate glass, silica, fused silica. The glass core 202 may include one or more additives, such as Al₂O₃, B₂O₃, MgO, CaO, SrO, BaO, SnO₂, Na₂O, K₂O, SrO, P₂O₃, ZrO₂, Li₂O, Ti, and Zn. The glass core 202 may comprise silicon and oxygen, as well as any one or more of aluminum, boron, magnesium, calcium, barium, tin, sodium, potassium, strontium, phosphorus, zirconium, lithium, titanium, and zinc. The glass core 202 may include at least 20-40 percent silicon by weight, at least 20-40 percent oxygen by weight, and at least 5 percent aluminum by weight. For example, some embodiments of the glass core 202 may include, e.g., at least 20-23 percent silicon and at least 20-26 percent oxygen by weight.

The thickness of the circuit board 102 may be any suitable thickness, such as 100 micrometers to 5 millimeters. The thickness of the substrate core 202 may be any suitable thickness, such as 50 micrometers to 1.7 millimeters. The circuit board 102 can have any suitable length and width, such as 5-500 millimeters. Although shown as a rectangle, it should be appreciated that the circuit board 102 may be any suitable shape and may have protrusions, cutouts, etc., in order to accommodate, fit, or touch other components of a device. In the illustrative embodiment, the circuit board 102 is planar. In other embodiments, the circuit board 102 may be non-planar. The cavity 214 may be any suitable size, such as a length and/or width of 1-20 millimeters.

In an illustrative embodiment, the die 104 above the power components 208, 210 is a processor die and other dies 106 may be memory dies communicatively coupled to the processor die 104. In other embodiments, the die 104 and/or the dies 106 may be any suitable die, such as one or more processor dies, memory dies, central processing units (CPUs), graphics processing units (CPUs), any other suitable processing units (xPUs), accelerator circuits, a field-programmable gate arrays (FPGA), application-specific integrated circuits (ASICs), etc. The dies 104, 106 may be connected to contact pads or vias 220 on the circuit board 102 through solder balls 222.

As referenced above, the power components 208, 210 may be any suitable power components, such as DTCs 208, 210 and/or magnetic inductor arrays 208, 210. In an illustrative embodiment, the DTCs 208, 210 are silicon dies that include an array of trenches, such as trenches that are 0.1-100 micrometers deep. The trenches may have a pitch of, e.g., 0.2-5 micrometers. The DTCs 208, 210 may include any suitable number of trenches, such as 1-10,000. One electrode for a capacitor may be conformal with the trenches, with a dielectric material on top of the electrode, and the other electrode on top of the dielectric material. The electrodes for the capacitor may be coupled to traces 218 or pads 218 defined in the build-up layers 204, 206. The DTCs 208, 210 may be connected to the die 104, the dies 106, a component connected to the circuit board 102, etc., through various connections in the integrated circuit component 100, such as traces 218, vias 220, through holes 216, etc. The power components 208, 210 may have any suitable dimensions, such as a height of 25 micrometers to 650 micrometers and a length and/or width of 1-20 millimeters.

The power components 208, 210 may be attached together in any suitable manner, such as by using an adhesive 212, such as die attach film 212. Additionally or alternatively, the power components 208, 210 may be attached together using, e.g., glue epoxy, bump bonding, hybrid bonding, fusion bonding, thermocompression bonding, wafer on wafer bonding, wafer-on-wafer hybrid bonding, solder with underfill, and/or the like.

The volume of the cavity 214 that is not taken up by the power components 208, 210 may be filled with any suitable filler material 224. For example, the filler material 224 may be prepreg, Ajinomoto build-up film (ABF), photoimageable dielectric, an inorganic dielectric material, an organic dielectric material, an oxide, a nitride, silicon dioxide, silicon nitride, polymer, epoxy, polyimide, polymer composites with inorganic fillers, and/or the like. The filler material 224 may be applied using any suitable approach, such as compression molding, vacuum lamination, hot press, chemical vapor deposition, physical vapor deposition, and/or the like.

In an illustrative embodiment, plated through holes 216 extend from the top surface 226 of the substrate core 202 to the bottom surface 230 of the substrate core 202. The through holds 216 may transport power and/or data signals through the substrate core 202.

The circuit board 102 includes traces 218 and vias 220. The traces 218 and vias 220 may be made of any suitable conductive material, such as copper or aluminum.

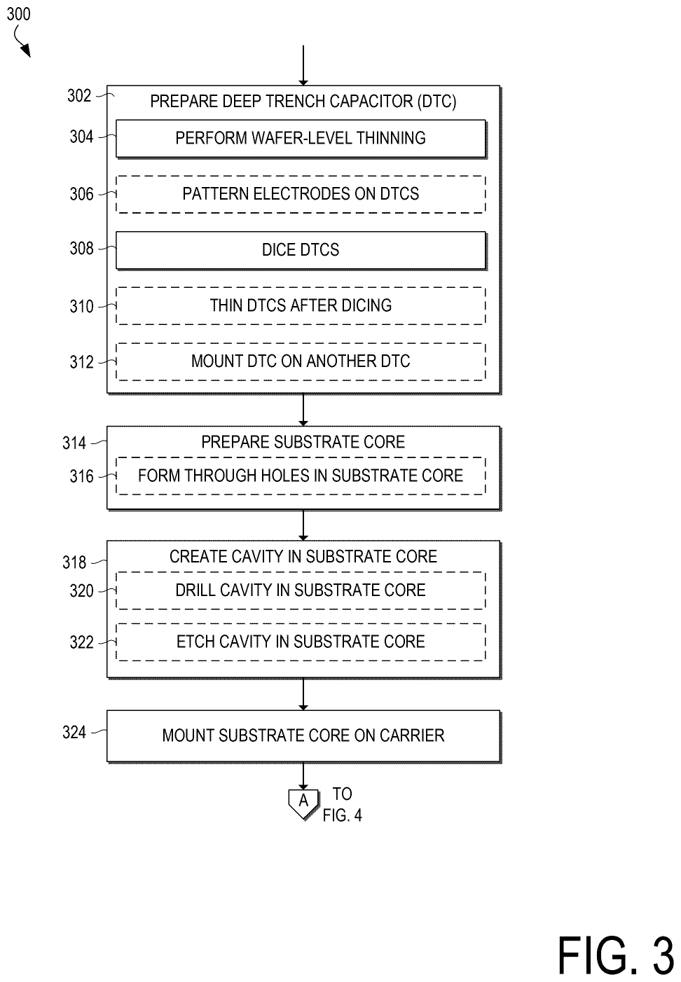

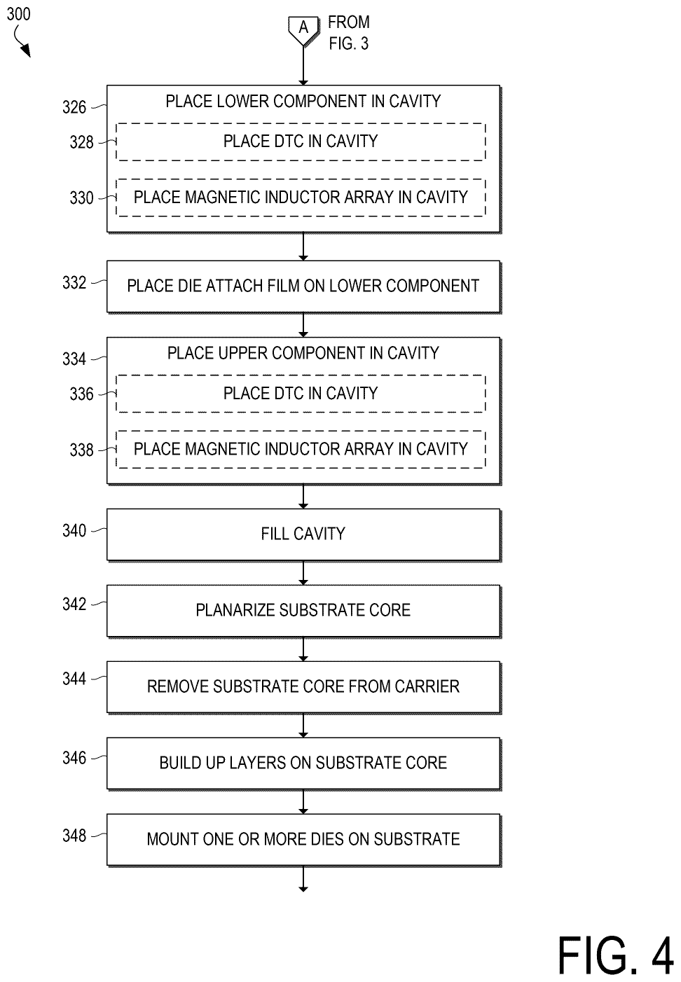

Referring now to FIGS. 3 and 4, in one embodiment, a flowchart for a method 300 for creating the integrated circuit component 100 is shown. The method 300 may be executed by a technician and/or by one or more automated machines. In some embodiments, one or more machines may be programmed to do some or all of the steps of the method 300. Such a machine may include, e.g., a memory, a processor, data storage, etc. The memory and/or data storage may store instructions that, when executed by the machine, cause the machine to perform some or all of the steps of the method 300. The method 300 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, 3D photolithography, screen printing, ink jet printing, etc. It should be appreciated that the method 300 is merely one embodiment of a method to create one embodiment of a system and other methods may be used to create any suitable embodiment of the system. In some embodiments, steps of the method 300 may be performed in a different order than that shown in the flowchart.

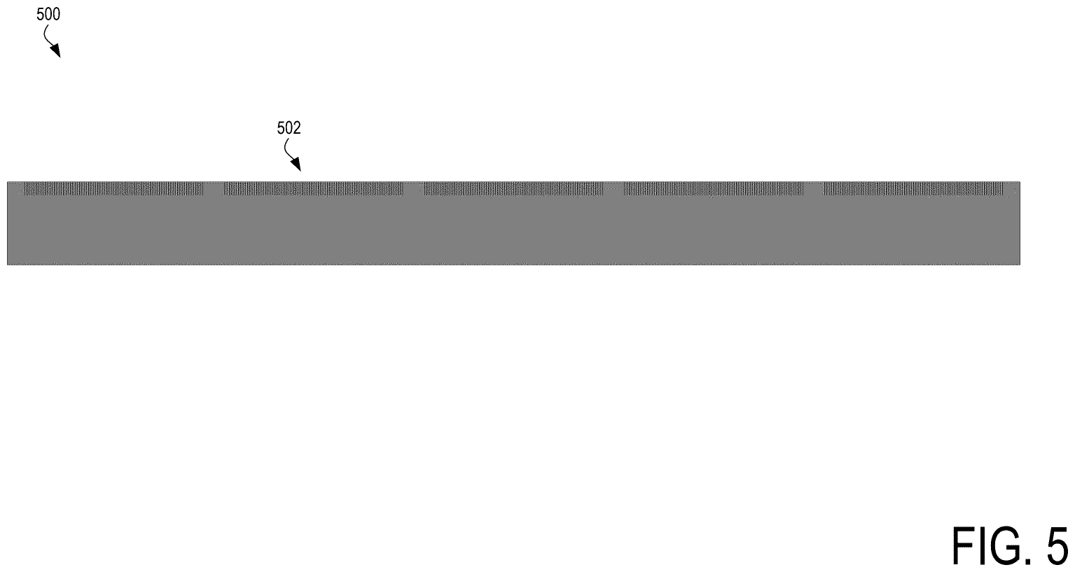

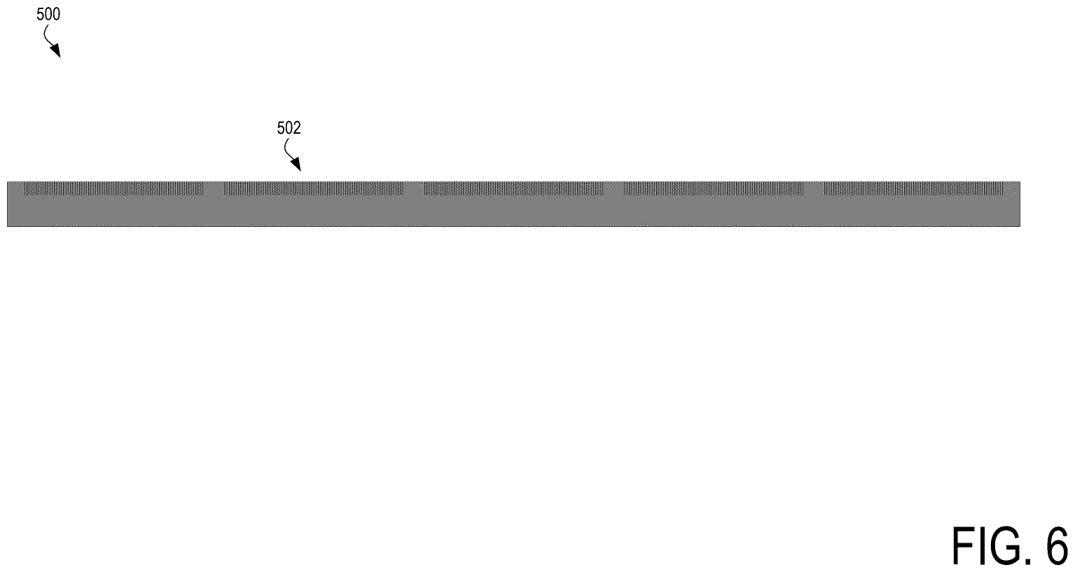

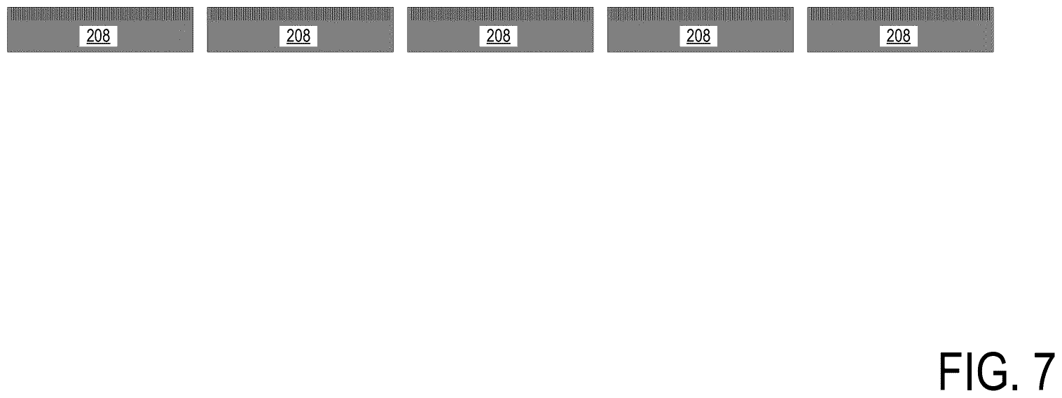

The method 300 begins in block 302, in which one or more DTCs 208, 210 are prepared. In an illustrative embodiment, a wafer 500 with multiple arrays of deep trenches 502 is fabricated. A cross-section of part of such a wafer 500 is shown in FIG. 5. In some embodiments, wafer-level thinning may be performed in block 304, leading to a thinner wafer 500, as shown in FIG. 6. Additionally or alternatively, in other embodiments, the DTCs 208, 210 may be thinned after dicing or the DTCs 208, 210 may not be thinned. In block 306, in some embodiments, electrodes may be patterned on the DTCs 208, 210. Additionally or alternatively, in some embodiments, electrodes may be patterned on the DTCs 208, 210 in another step of the manufacturing process, such as when forming the build-up layers 204, 206. In block 308, the wafer 500 is diced to form DTCs 208, as shown in FIG. 7. In some embodiments, in block 310, the DTCs 208 may be thinned after dicing. At this stage, in some embodiments, the upper DTC 208 may be mounted on the lower DTC 210, such as by using die attach film 212. In some embodiments, in block 312, the upper DTC 208 may be mounted on the lower DTC 210 at the wafer level, such as by wafer-on-wafer bonding. In other embodiments, the DTCs 208, 210 may be attached at a later time, as described below. In some embodiments, pre-fabricating the stack of power components 208, 210 may allow for testing of the stack of power components 208, 210 before integration into the substrate core 202, increasing yield and reducing cost.

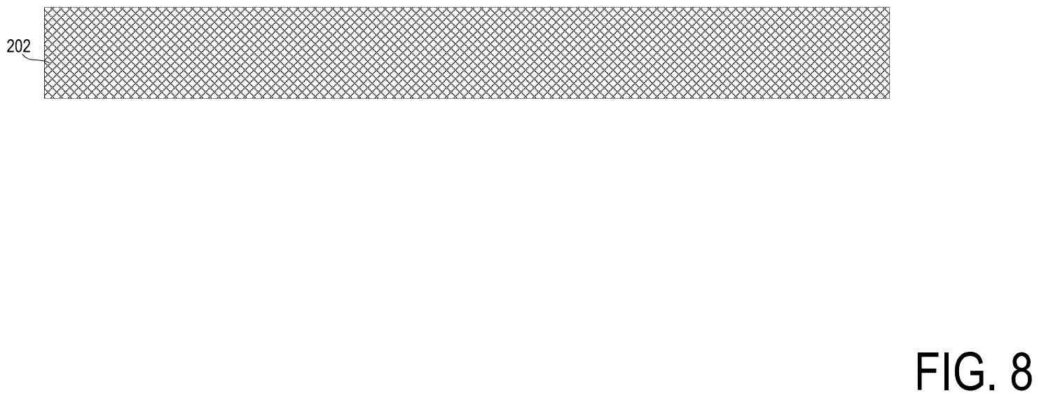

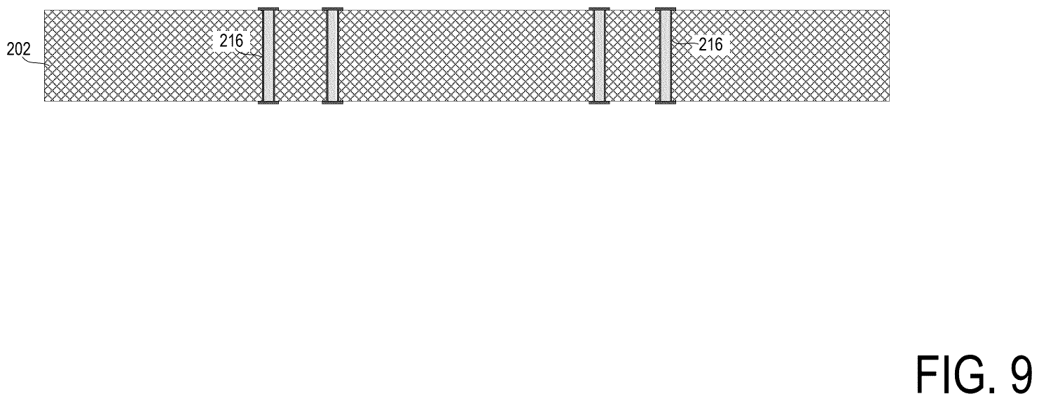

In block 314, a substrate core 202 is prepared, such as by dicing, polishing, etc., as shown in FIG. 8. In some embodiments, in block 316, through holes 216 are formed in the substrate core 202, as shown in FIG. 9.

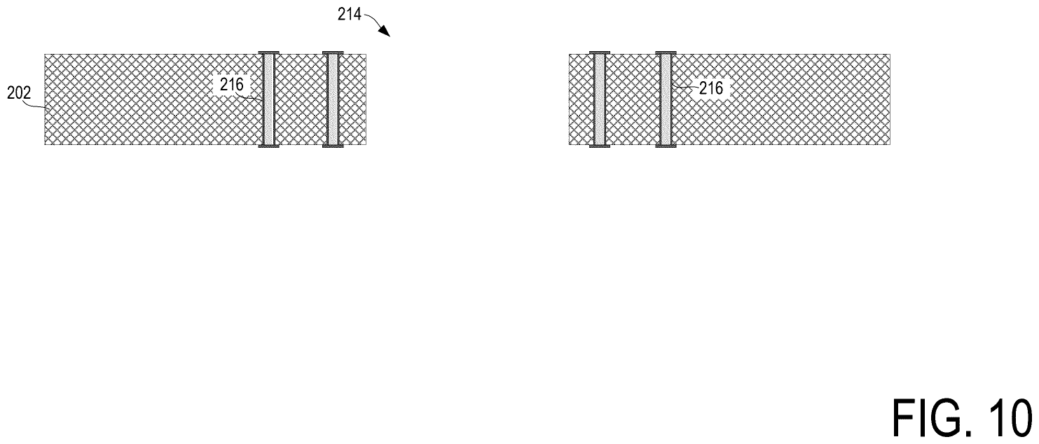

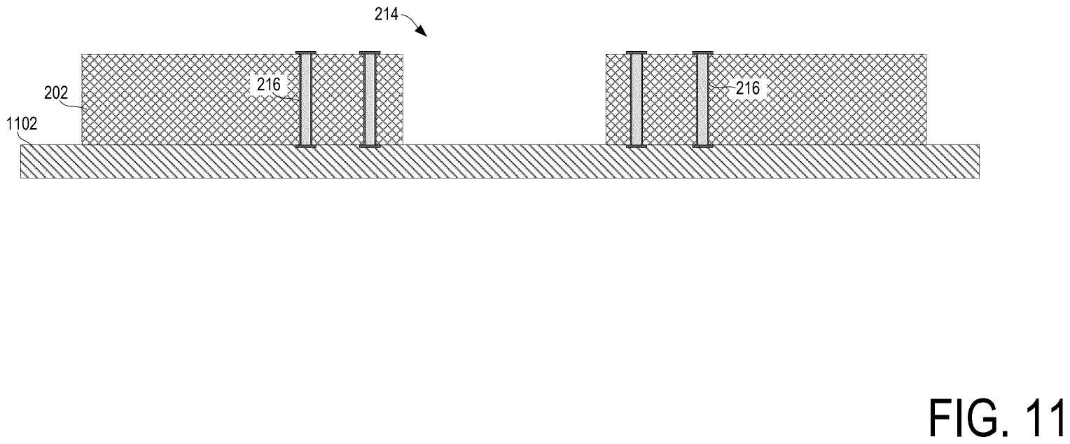

In block 318, a cavity 214 is formed in the substrate core 202, as shown in FIG. 10. The cavity 214 may be formed in any suitable manner. For example, in some embodiments, the cavity 214 may be formed by drilling out the cavity 214 in block 320, such as by using a mechanical or laser drill. In other embodiments, the cavity 214 may be etched away in block 322. In block 324, the substrate core 202 is mounted on a carrier 1102, as shown in FIG. 11. The carrier 1102 may be, e.g., a silicon or other substrate, a glass substrate, a tape material, and/or the like.

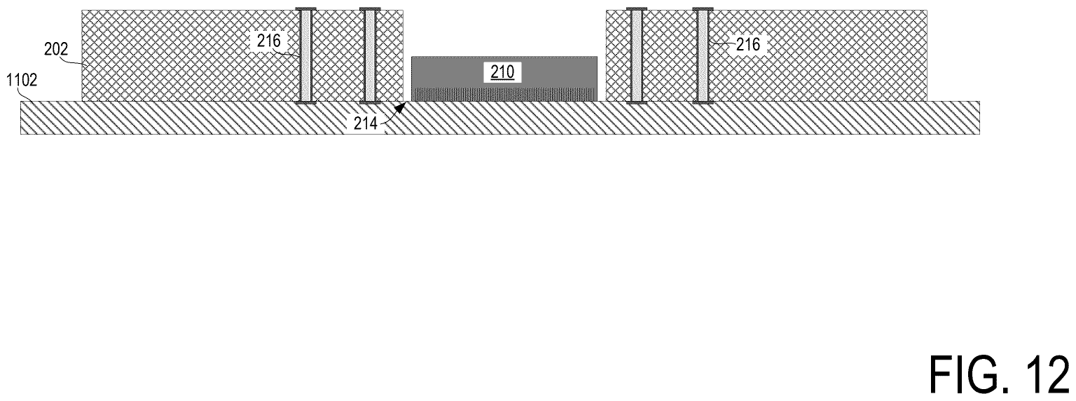

Referring now to FIG. 4, in block 326, the lower power component 210 is placed in the cavity 214, as shown in FIG. 12. In some embodiments, a DTC 210 is placed in block 328. In other embodiments, a magnetic inductor array 210 may be placed in block 330.

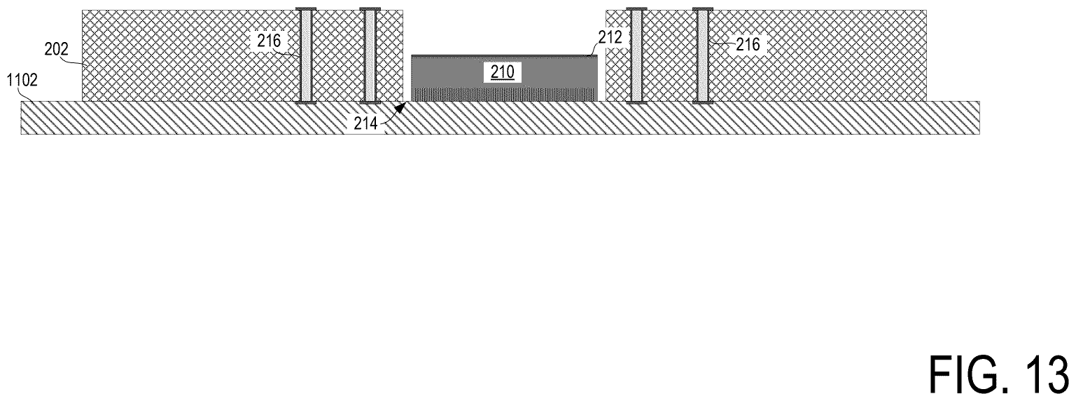

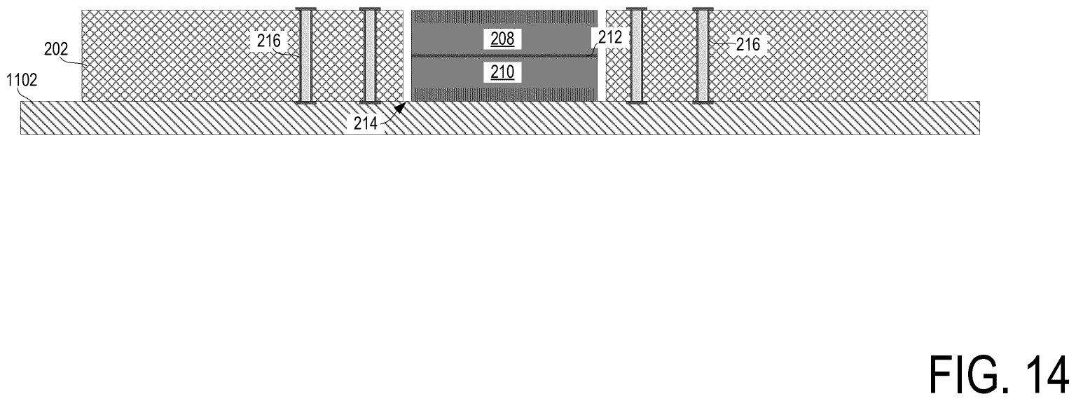

In block 332, a die attach film 212 is placed on the DTC 210, as shown in FIG. 13. In other embodiments, the power components 208, 210 may joined together in another manner, such as by using glue epoxy, bump bonding, hybrid bonding, fusion bonding, thermocompression bonding, etc. In block 334, an upper component 208 is placed in the cavity 214, as shown in FIG. 14. In one embodiment, a DTC 208 is placed in the cavity 214 in block 336. In another embodiment, a magnetic inductor array 214 is placed in the cavity 214 in block 338.

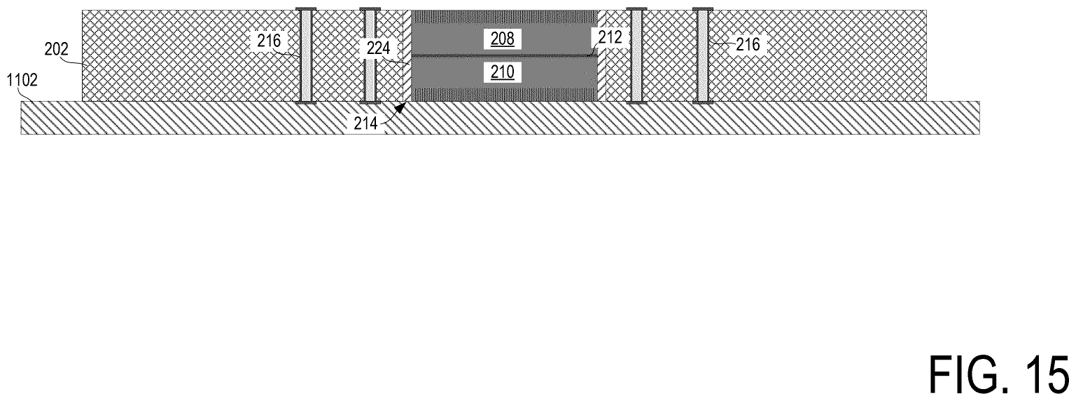

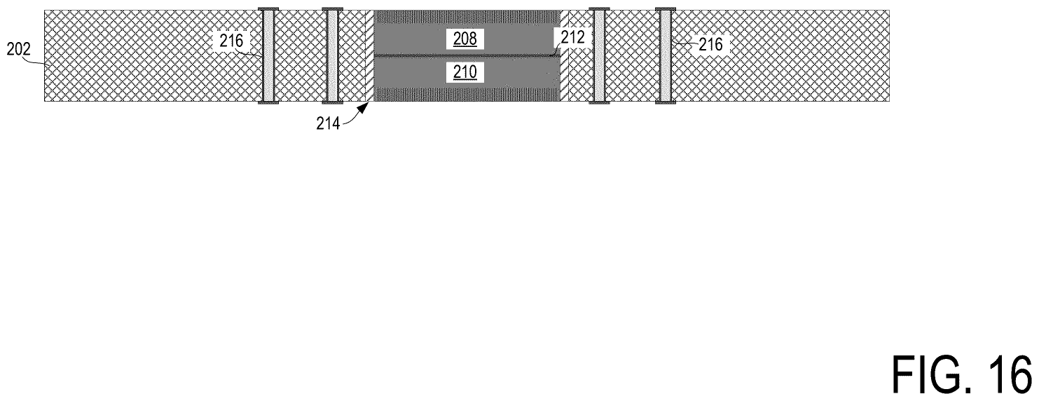

In block 340, the cavity 214 is filled with filler material 224, such as prepreg, ABF, photoimageable dielectric, etc. The filler material 224 may be applied using any suitable approach, such as compression molding, vacuum lamination, hot press, chemical vapor deposition, physical vapor deposition, and/or the like. In block 342, the substrate core 202 is planarized, as shown in FIG. 15. In block 344, the substrate core 202 is removed from the carrier 1102, as shown in FIG. 16.

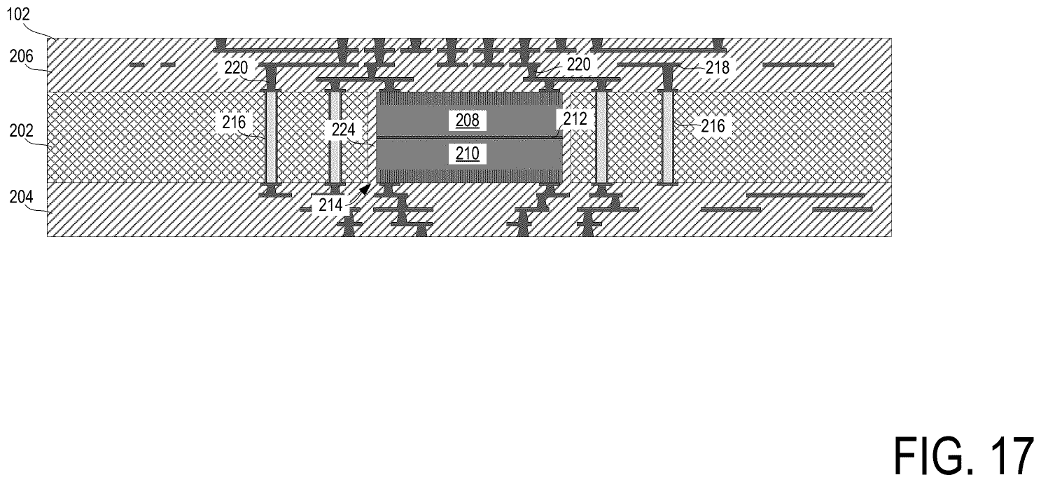

In block 346, build-up layers 204, 206 are built up on the substrate core 202, as shown in FIG. 17. The build-up layers 204, 206 may be created using any suitable set of techniques, such as electroplating, electroless plating, photolithography, etching, etc. In block 348, one or more dies 104, 106 are mounted on the substrate, completing the integrated circuit component 100, as shown in FIG. 2.

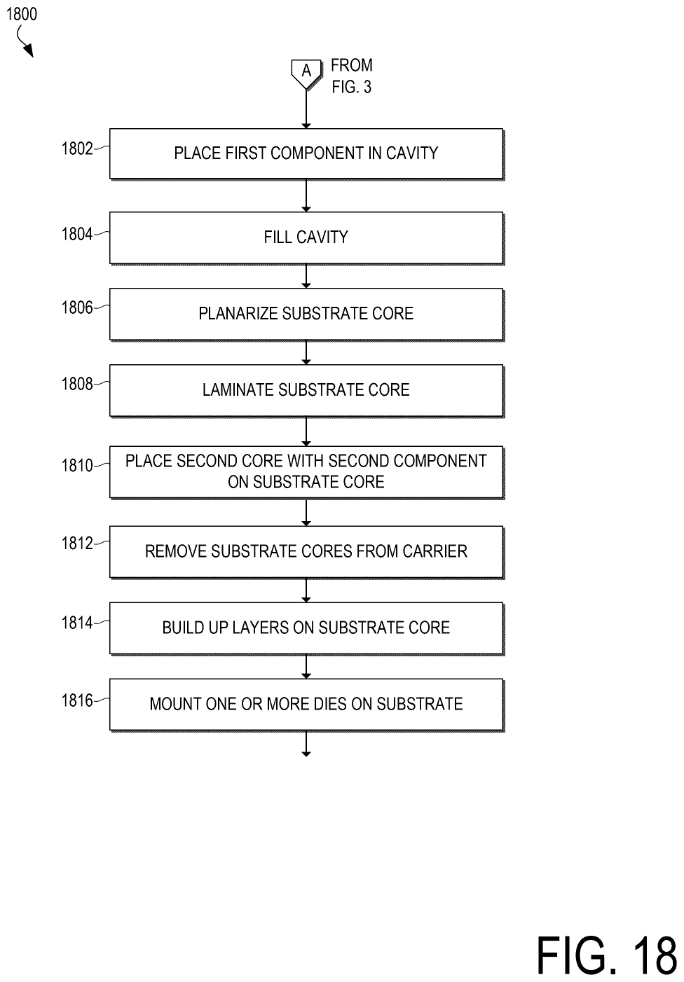

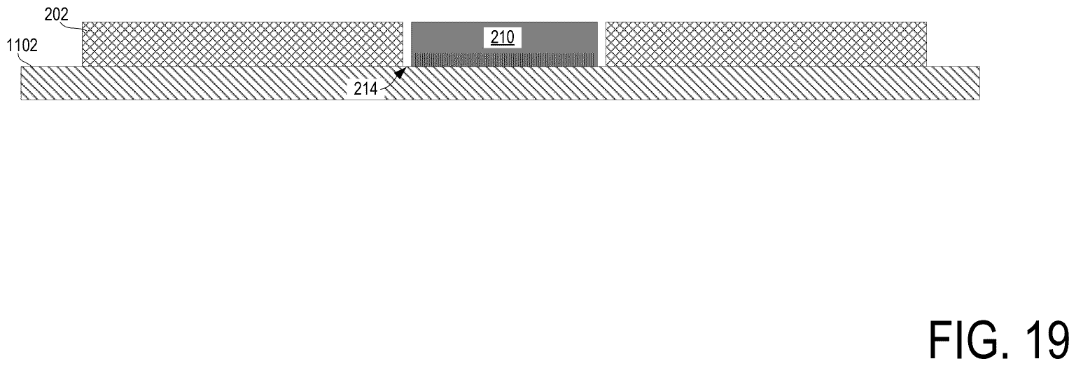

Referring now to FIG. 18, in one embodiment, a flowchart for an alternate method 1800 for creating a substrate core for the integrated circuit component 100 is shown. The method 1800 may begin with blocks 302-324 of the method 300 described above. After block 324, the method 1800 proceeds to block 1802, in which the first power component 210 is placed in the cavity 214, as shown in FIG. 19. In the embodiment depicted in FIG. 19, the power component 210 has about the same height as the substrate core 202.

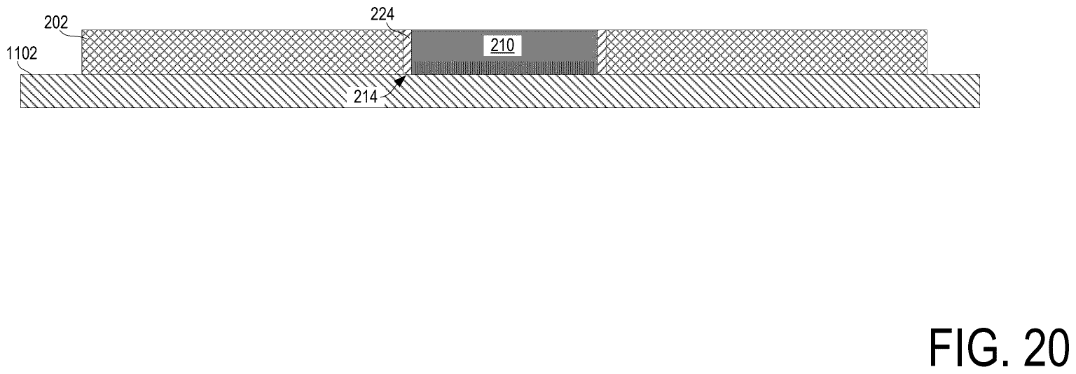

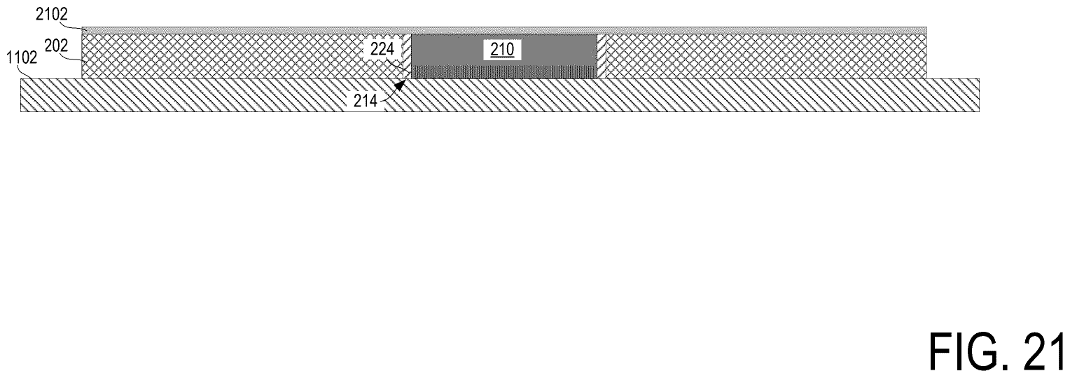

In block 1804, the cavity is filled, and in block 1806, the substrate core 202 is planarized, as shown in FIG. 20. In block 1808, a laminate layer 2102 is placed on the substrate core 202, as shown in FIG. 21.

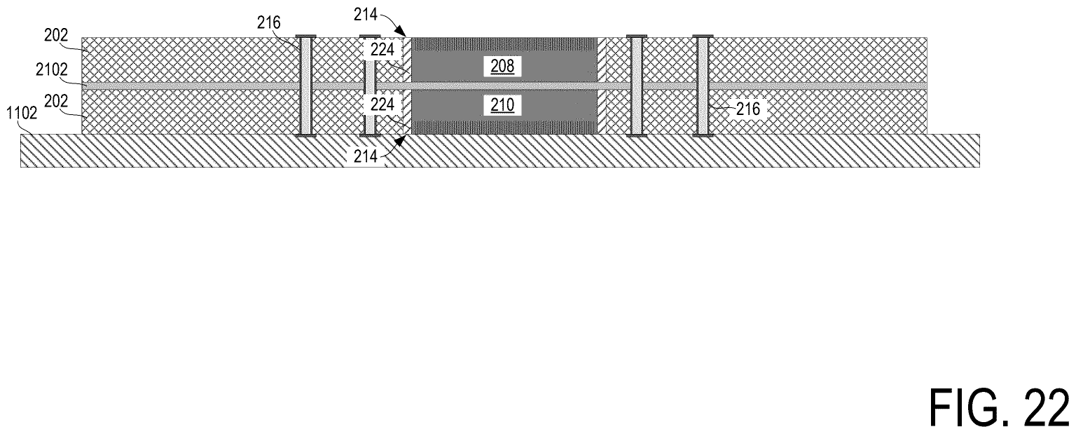

In block 1810, a second substrate core 202 with a second power component 208 is placed on the first substrate core 202, as shown in FIG. 22. In another embodiment, the second substrate core 202 may be placed on the first substrate core 202 without the second power component 208, and the second power component 208 may be added in a similar manner as the first power component 210.

In block 1812, the substrate core 202 is removed from the carrier 1102. In block 1814, build-up layers 204, 206 are built up on the substrate core 202. In block 1816, one or more dies 104, 106 are mounted on the substrate, completing the integrated circuit component 100.

It should be appreciated that the embodiments described above are merely some possible embodiments, and other embodiments with different features or different combinations of the features disclosed herein are envisioned as well. A description of some but not all of the envisioned embodiments are described below.

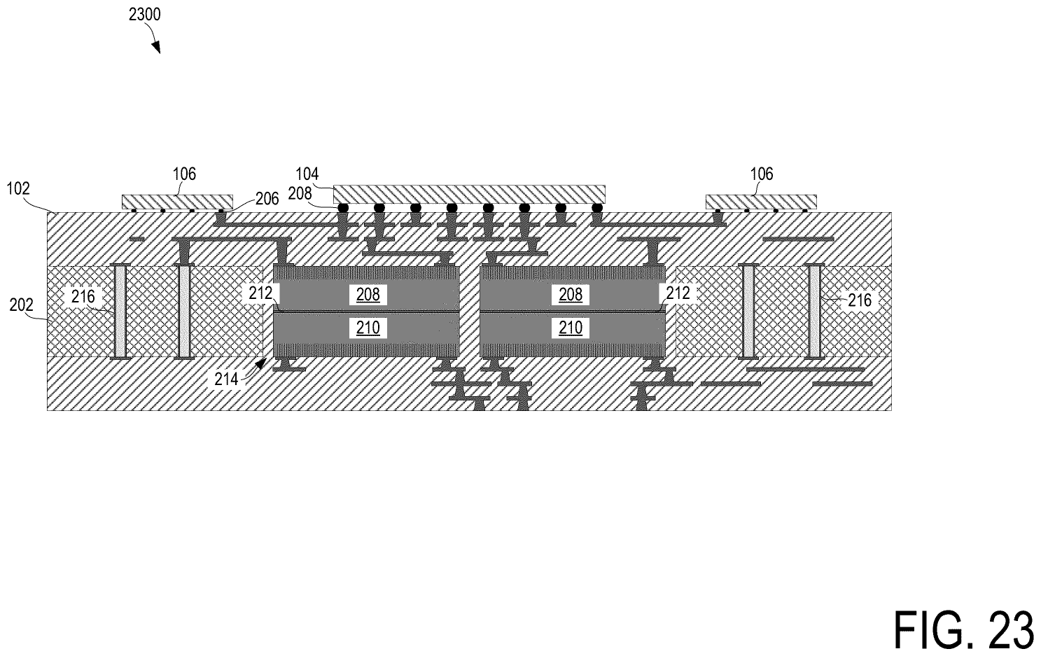

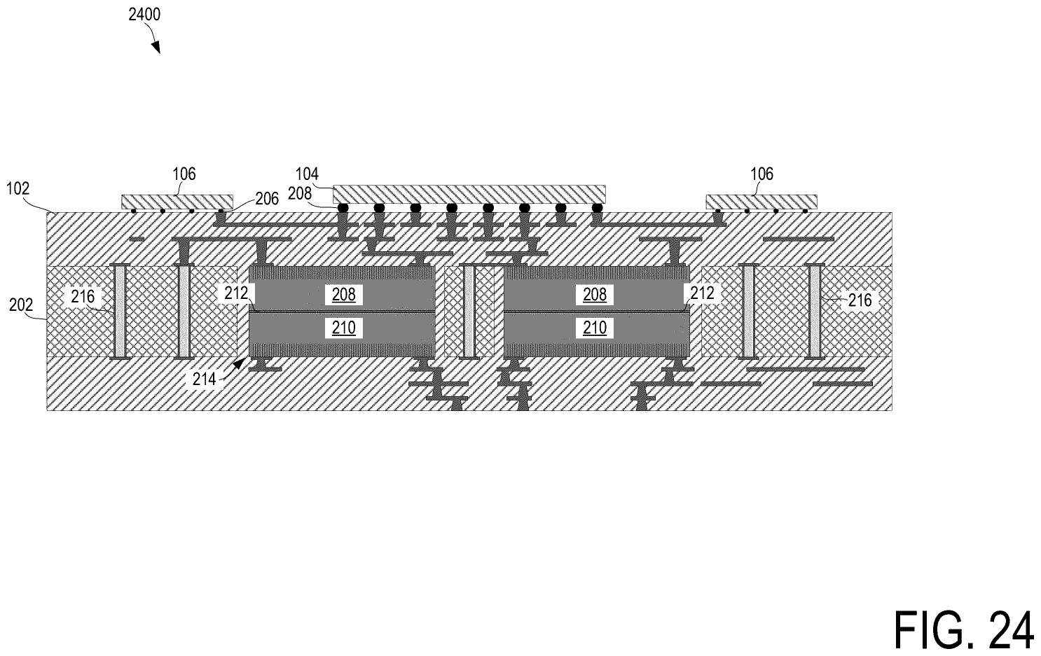

Referring now to FIG. 23, in some embodiments, an integrated circuit component 2300 may include two or more stacks of power components 208, 210 in the same cavity 214. Additionally or alternatively, in some embodiments, an integrated circuit component 2400 may include two or more stacks of power components 208, 210 in different cavities 214, as shown in FIG. 24.

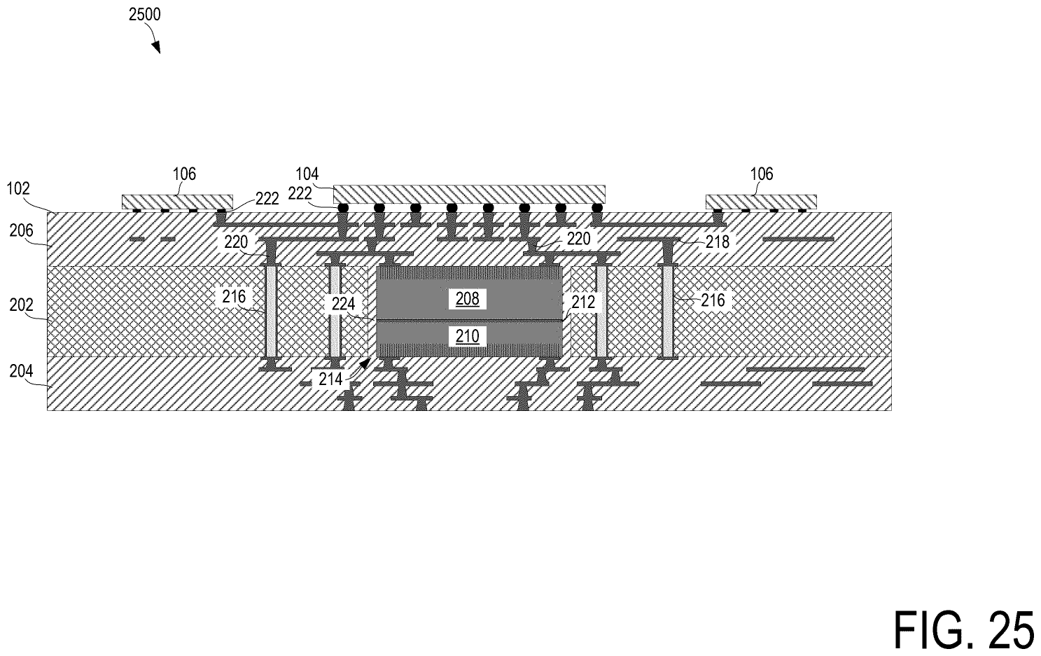

In the embodiment described above in regard to FIG. 2, the power components 208, 210 have about the same height. In other embodiments, the power components 208, 210 may have different heights. For example, the lower power component 210 may have a smaller height than the height of the upper power component 208, as shown in an integrated circuit component 2500 in FIG. 25.

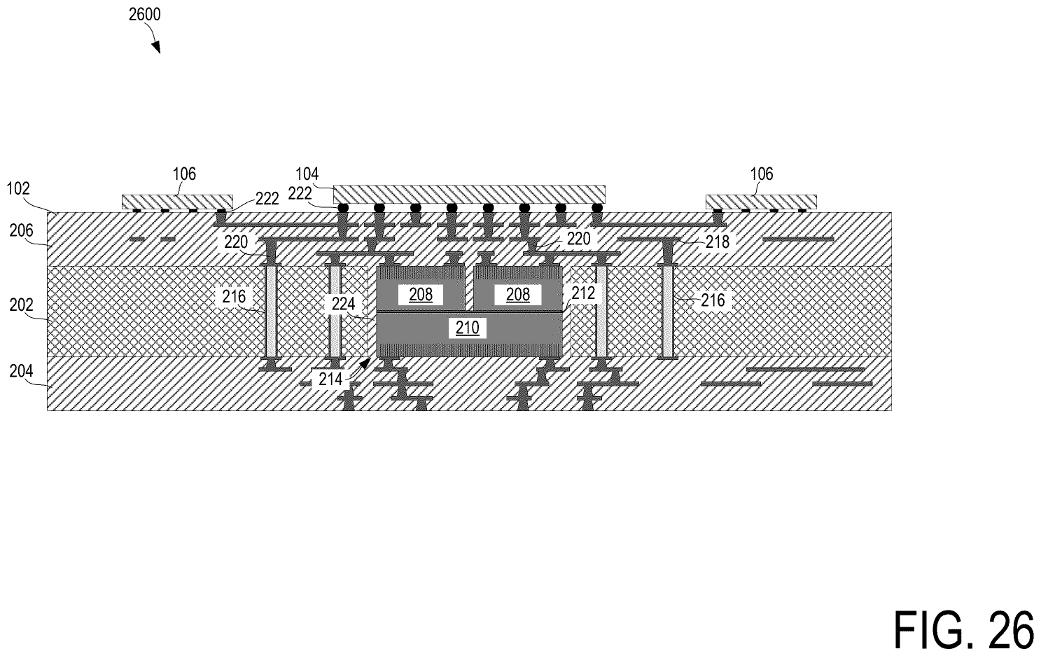

In the embodiment described above in regard to FIG. 2, the stack of power components includes one lower power component 210 and one upper power component 208. In another embodiment, several lower power components 210 and/or several upper power components 208 may be included in one stack. For example, as shown in FIG. 26, in one embodiment, two upper power components 208 may be disposed on one lower power component 210 of an integrated circuit component 2600.

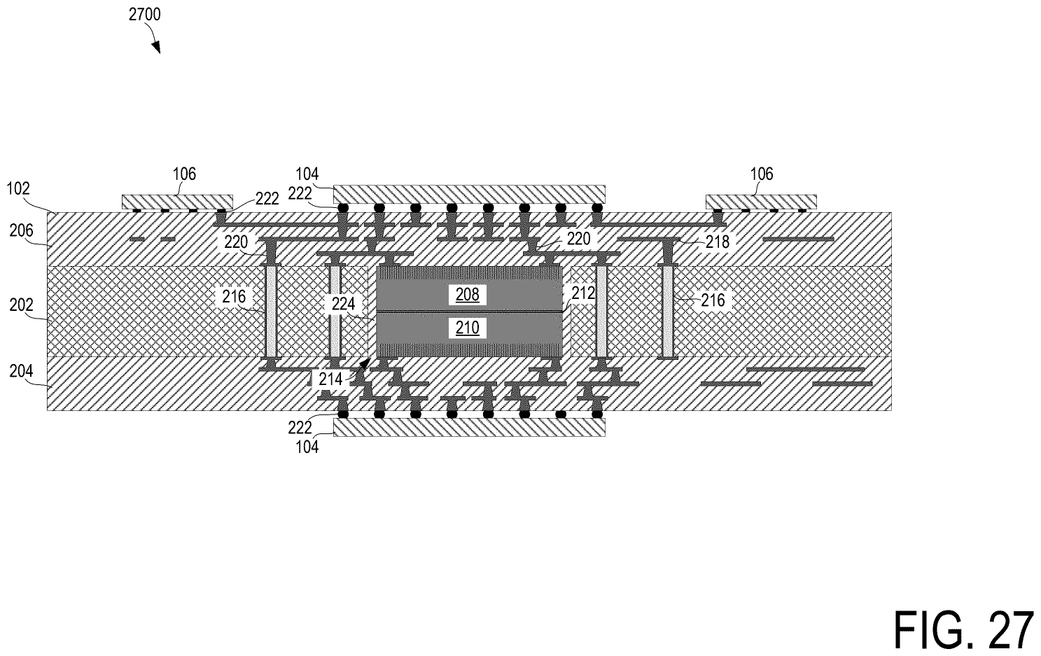

In another possible embodiment, an integrated circuit component 2700 may include a die 104 mounted on the bottom side of the circuit board 102, as shown in FIG. 27.

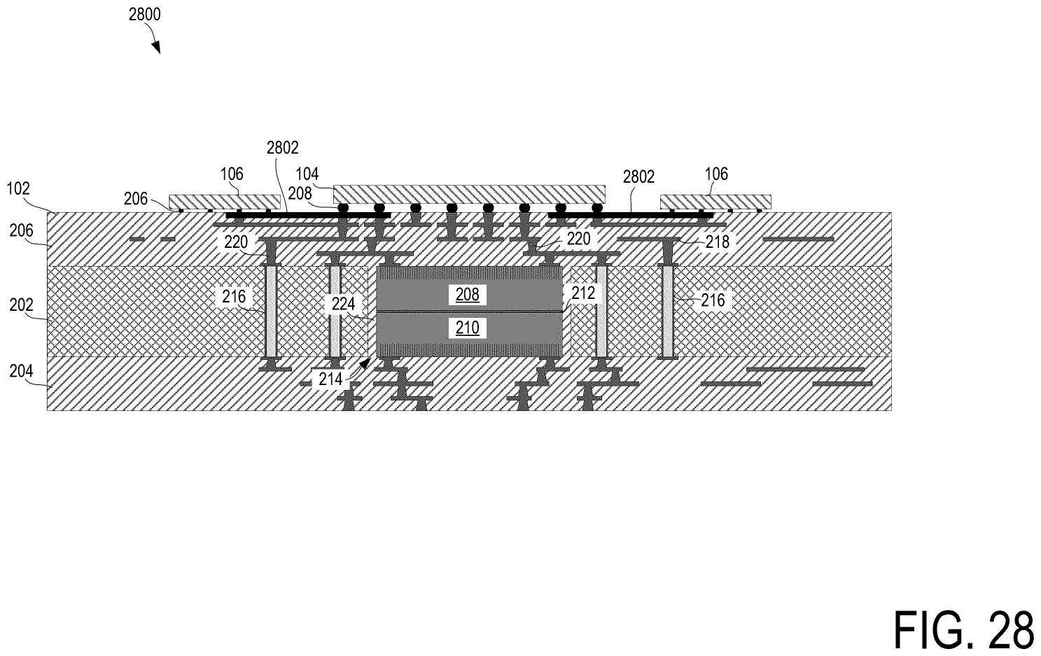

In another possible embodiment, as shown in FIG. 28 a bridge die 2802 may be disposed on or within the circuit board 102 of an integrated circuit component 2800, such as within the upper build-up layers 206. The bridge die 2802 can provide interconnects between various components, such as between the dies 104, 106 of the integrated circuit component 100 or between a die 104, 106 and a connection external to the integrated circuit component 100. The bridge die 2802 may be embodied as, e.g., an embedded multi-die interconnect bridge (EMIB) or an omni-directional interconnect (ODI).

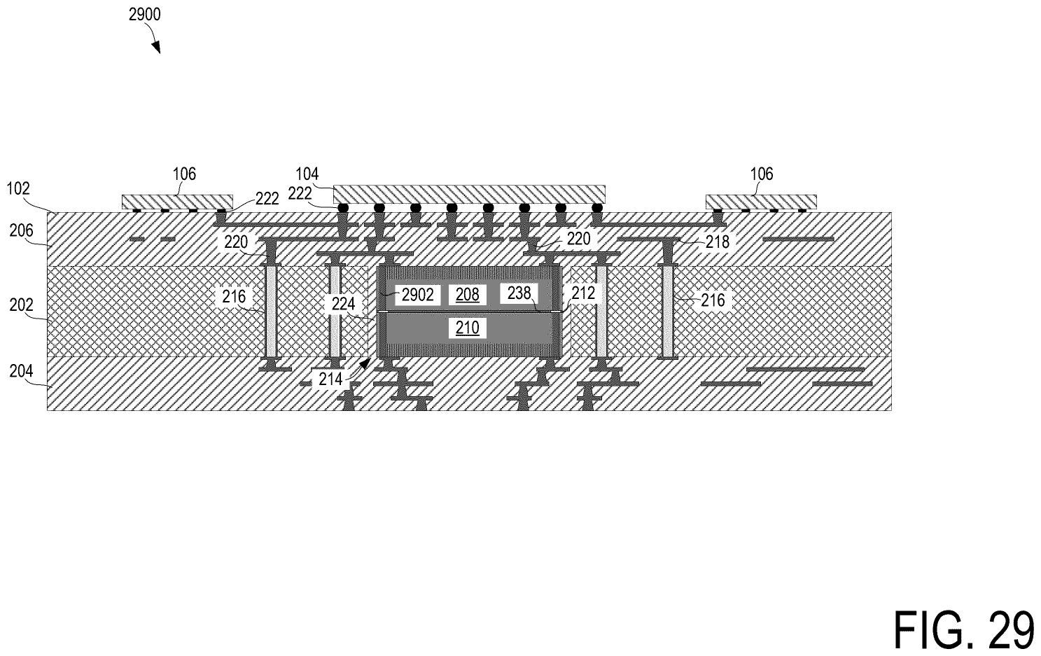

In another possible embodiment, through-silicon vias (TSVs) 2902 may be present within one or both of the power components 208, 210 of an integrated circuit component 2900, as shown in FIG. 29. The TSVs 2902 may allow for a connection to the upper power component 208 from the lower build-up layer 204 or vice-versa. Additionally or alternatively, the TSVs 2902 may allow for the power components 208, 210 to be connected together, such as by connecting DTCs 208, 210 together in parallel or series. The TSVs 2902 may be made of any suitable conductive material, such as copper, tungsten, polysilicon, etc. In some embodiments, conductor 238 may connect the TSV 2902 in one power component 208, 210 to the other power component 208, 210. The conductor 238 may be copper, solder, etc. Additionally or alternatively, the power components 208, 210 may be joined in a manner that does not require a separate layer of a conductor 238, such as hybrid bonding. In an illustrative embodiment, the TSVs 2902 are disposed towards an edge of the power components 208, 210. In other embodiments, the TSVs 2902 may be disposed in other locations, such as closer towards the middle of the power components 208, 210.

It should be appreciated that the integrated circuit component 100 and other integrated circuit components described herein may have additional components not shown, such as additional semiconductor dies, active component, passive components, heat management components such as integrated heat spreaders and heat sinks, etc. In some embodiments, power components 208, 210 may be embedded in a circuit board 102 below a die 104 in an integrated circuit component 100, as shown in several figures above. In other embodiments, the power components 208, 210 may be embedded in any suitable circuit board 102, such as a motherboard, daughterboard, riser board, power distribution board, mezzanine board, auxiliary board, and/or the like.

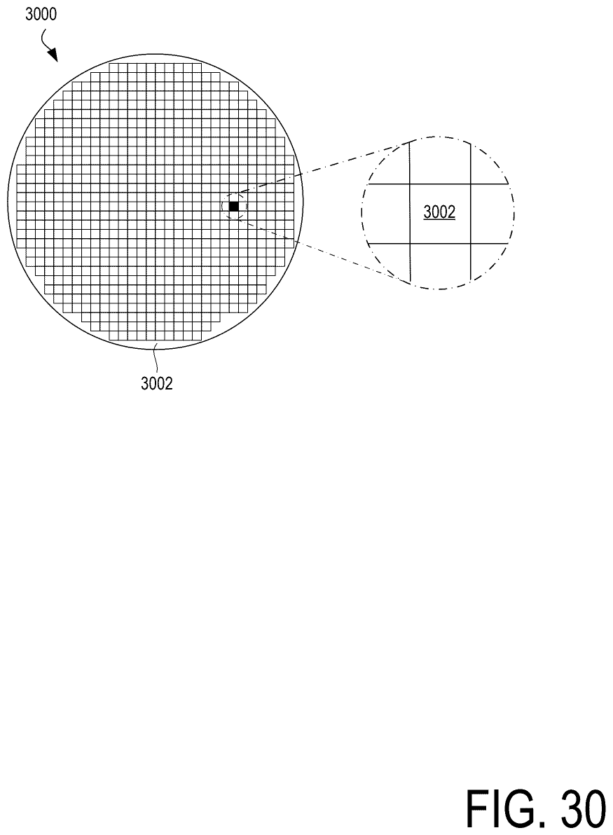

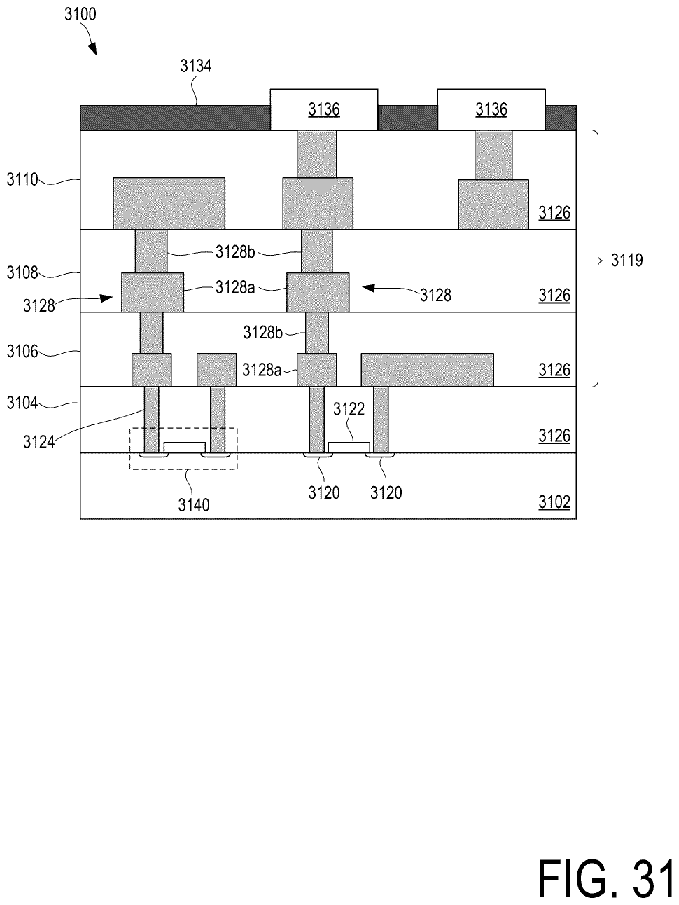

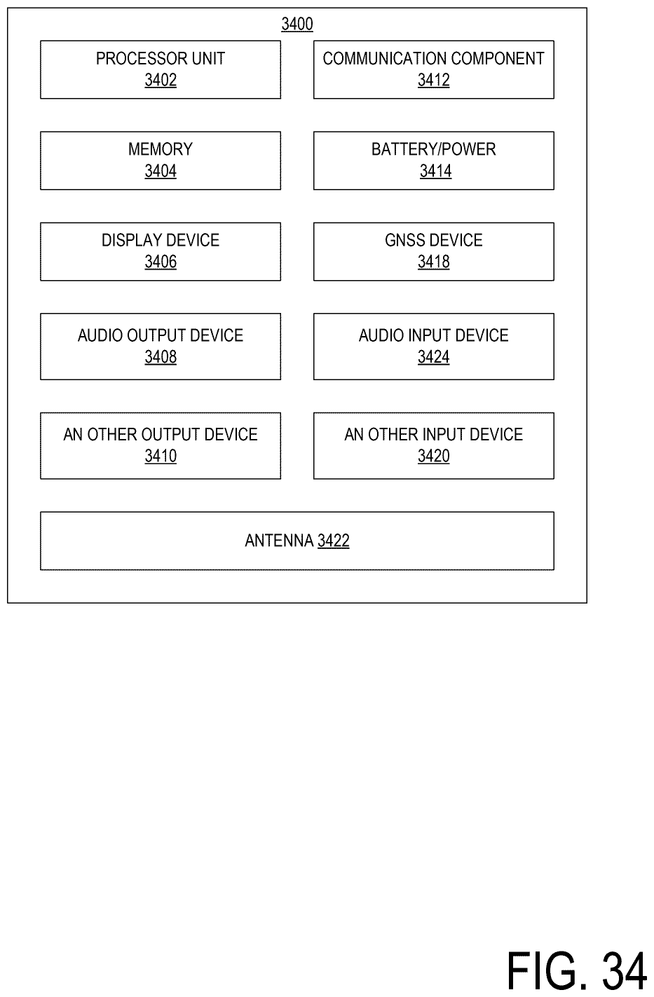

FIG. 30 is a top view of a wafer 3000 and dies 3002 that may be included in any of the integrated circuit components 100 disclosed herein (e.g., as any suitable ones of the power components 208, 210 or dies 104). The wafer 3000 may be composed of semiconductor material and may include one or more dies 3002 having integrated circuit structures formed on a surface of the wafer 3000. The individual dies 3002 may be a repeating unit of an integrated circuit product that includes any suitable integrated circuit. After the fabrication of the semiconductor product is complete, the wafer 3000 may undergo a singulation process in which the dies 3002 are separated from one another to provide discrete “chips” of the integrated circuit product. The die 3002 may be any of the power components 208, 210 or dies 104 disclosed herein. The die 3002 may include one or more transistors (e.g., some of the transistors 3140 of FIG. 31, discussed below), supporting circuitry to route electrical signals to the transistors, passive components (e.g., signal traces, resistors, capacitors, or inductors), and/or any other integrated circuit components. In some embodiments, the wafer 3000 or the die 3002 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 3002. For example, a memory array formed by multiple memory devices may be formed on a same die 3002 as a processor unit (e.g., the processor unit 3402 of FIG. 34) or other logic that is configured to store information in the memory devices or execute instructions stored in the memory array. Various ones of the integrated circuit components 100 disclosed herein may be manufactured using a die-to-wafer assembly technique in which some power components 208, 210 or dies 104 are attached to a wafer 3000 that include others of the power components 208, 210 or dies 104, and the wafer 3000 is subsequently singulated.

FIG. 31 is a cross-sectional side view of an integrated circuit device 3100 that may be included in any of the integrated circuit components 100 disclosed herein (e.g., in any of the power components 208, 210 or dies 104). One or more of the integrated circuit devices 3100 may be included in one or more dies 3002 (FIG. 30). The integrated circuit device 3100 may be formed on a die substrate 3102 (e.g., the wafer 3000 of FIG. 30) and may be included in a die (e.g., the die 3002 of FIG. 30). The die substrate 3102 may be a semiconductor substrate composed of semiconductor material systems including, for example, n-type or p-type materials systems (or a combination of both). The die substrate 3102 may include, for example, a crystalline substrate formed using a bulk silicon or a silicon-on-insulator (SOI) substructure. In some embodiments, the die substrate 3102 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 3102. Although a few examples of materials from which the die substrate 3102 may be formed are described here, any material that may serve as a foundation for an integrated circuit device 3100 may be used. The die substrate 3102 may be part of a singulated die (e.g., the dies 3002 of FIG. 30) or a wafer (e.g., the wafer 3000 of FIG. 30).

The integrated circuit device 3100 may include one or more device layers 3104 disposed on the die substrate 3102. The device layer 3104 may include features of one or more transistors 3140 (e.g., metal oxide semiconductor field-effect transistors (MOSFETs)) formed on the die substrate 3102. The transistors 3140 may include, for example, one or more source and/or drain (S/D) regions 3120, a gate 3122 to control current flow between the S/D regions 3120, and one or more S/D contacts 3124 to route electrical signals to/from the S/D regions 3120. The transistors 3140 may include additional features not depicted for the sake of clarity, such as device isolation regions, gate contacts, and the like. The transistors 3140 are not limited to the type and configuration depicted in FIG. 31 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

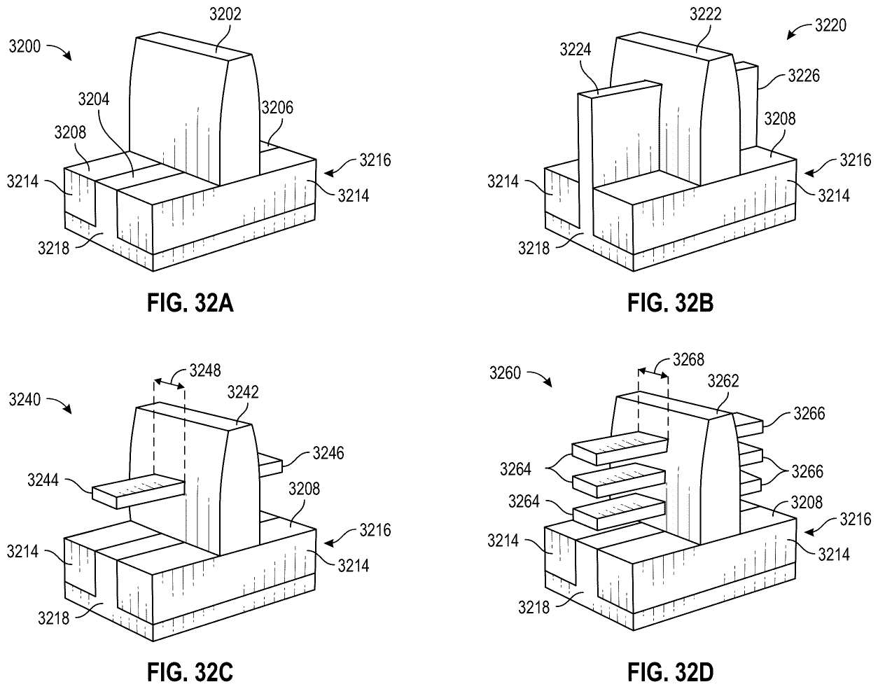

FIGS. 32A-32D are simplified perspective views of example planar, FinFET, gate-all-around, and stacked gate-all-around transistors. The transistors illustrated in FIGS. 32A-32D are formed on a substrate 3216 having a surface 3208. Isolation regions 3214 separate the source and drain regions of the transistors from other transistors and from a bulk region 3218 of the substrate 3216.

FIG. 32A is a perspective view of an example planar transistor 3200 comprising a gate 3202 that controls current flow between a source region 3204 and a drain region 3206. The transistor 3200 is planar in that the source region 3204 and the drain region 3206 are planar with respect to the substrate surface 3208.

FIG. 32B is a perspective view of an example FinFET transistor 3220 comprising a gate 3222 that controls current flow between a source region 3224 and a drain region 3226. The transistor 3220 is non-planar in that the source region 3224 and the drain region 3226 comprise “fins” that extend upwards from the substrate surface 3228. As the gate 3222 encompasses three sides of the semiconductor fin that extends from the source region 3224 to the drain region 3226, the transistor 3220 can be considered a tri-gate transistor. FIG. 32B illustrates one S/D fin extending through the gate 3222, but multiple S/D fins can extend through the gate of a FinFET transistor.

FIG. 32C is a perspective view of a gate-all-around (GAA) transistor 3240 comprising a gate 3242 that controls current flow between a source region 3244 and a drain region 3246. The transistor 3240 is non-planar in that the source region 3244 and the drain region 3246 are elevated from the substrate surface 3228.

FIG. 32D is a perspective view of a GAA transistor 3260 comprising a gate 3262 that controls current flow between multiple elevated source regions 3264 and multiple elevated drain regions 3266. The transistor 3260 is a stacked GAA transistor as the gate controls the flow of current between multiple elevated S/D regions stacked on top of each other. The transistors 3240 and 3260 are considered gate-all-around transistors as the gates encompass all sides of the semiconductor portions that extends from the source regions to the drain regions. The transistors 3240 and 3260 can alternatively be referred to as nanowire, nanosheet, or nanoribbon transistors depending on the width (e.g., widths 3248 and 3268 of transistors 3240 and 3260, respectively) of the semiconductor portions extending through the gate.

Returning to FIG. 31, a transistor 3140 may include a gate 3122 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 3140 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 3140 along the source-channel-drain direction, the gate electrode may consist of a U-shaped structure that includes a bottom portion substantially parallel to the surface of the die substrate 3102 and two sidewall portions that are substantially perpendicular to the top surface of the die substrate 3102. In other embodiments, at least one of the metal layers that form the gate electrode may simply be a planar layer that is substantially parallel to the top surface of the die substrate 3102 and does not include sidewall portions substantially perpendicular to the top surface of the die substrate 3102. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 3120 may be formed within the die substrate 3102 adjacent to the gate 3122 of individual transistors 3140. The S/D regions 3120 may be formed using an implantation/diffusion process or an etching/deposition process, for example. In the former process, dopants such as boron, aluminum, antimony, phosphorous, or arsenic may be ion-implanted into the die substrate 3102 to form the S/D regions 3120. An annealing process that activates the dopants and causes them to diffuse farther into the die substrate 3102 may follow the ion-implantation process. In the latter process, the die substrate 3102 may first be etched to form recesses at the locations of the S/D regions 3120. An epitaxial deposition process may then be carried out to fill the recesses with material that is used to fabricate the S/D regions 3120. In some implementations, the S/D regions 3120 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 3120 may be formed using one or more alternate semiconductor materials such as germanium or a group III-V material or alloy. In further embodiments, one or more layers of metal and/or metal alloys may be used to form the S/D regions 3120.

Electrical signals, such as power and/or input/output (I/O) signals, may be routed to and/or from the devices (e.g., transistors 3140) of the device layer 3104 through one or more interconnect layers disposed on the device layer 3104 (illustrated in FIG. 31 as interconnect layers 3106-3110). For example, electrically conductive features of the device layer 3104 (e.g., the gate 3122 and the S/D contacts 3124) may be electrically coupled with the interconnect structures 3128 of the interconnect layers 3106-3110. The one or more interconnect layers 3106-3110 may form a metallization stack (also referred to as an “ILD stack”) 3119 of the integrated circuit device 3100.

The interconnect structures 3128 may be arranged within the interconnect layers 3106-3110 to route electrical signals according to a wide variety of designs; in particular, the arrangement is not limited to the particular configuration of interconnect structures 3128 depicted in FIG. 31. Although a particular number of interconnect layers 3106-3110 is depicted in FIG. 31, embodiments of the present disclosure include integrated circuit devices having more or fewer interconnect layers than depicted.

In some embodiments, the interconnect structures 3128 may include lines 3128a and/or vias 3128b filled with an electrically conductive material such as a metal. The lines 3128a may be arranged to route electrical signals in a direction of a plane that is substantially parallel with a surface of the die substrate 3102 upon which the device layer 3104 is formed. For example, the lines 3128a may route electrical signals in a direction in and out of the page and/or in a direction across the page. The vias 3128b may be arranged to route electrical signals in a direction of a plane that is substantially perpendicular to the surface of the die substrate 3102 upon which the device layer 3104 is formed. In some embodiments, the vias 3128b may electrically couple lines 3128a of different interconnect layers 3106-3110 together.

The interconnect layers 3106-3110 may include a dielectric material 3126 disposed between the interconnect structures 3128, as shown in FIG. 31. In some embodiments, dielectric material 3126 disposed between the interconnect structures 3128 in different ones of the interconnect layers 3106-3110 may have different compositions; in other embodiments, the composition of the dielectric material 3126 between different interconnect layers 3106-3110 may be the same. The device layer 3104 may include a dielectric material 3126 disposed between the transistors 3140 and a bottom layer of the metallization stack as well. The dielectric material 3126 included in the device layer 3104 may have a different composition than the dielectric material 3126 included in the interconnect layers 3106-3110; in other embodiments, the composition of the dielectric material 3126 in the device layer 3104 may be the same as a dielectric material 3126 included in any one of the interconnect layers 3106-3110.

A first interconnect layer 3106 (referred to as Metal 1 or “M1”) may be formed directly on the device layer 3104. In some embodiments, the first interconnect layer 3106 may include lines 3128a and/or vias 3128b, as shown. The lines 3128a of the first interconnect layer 3106 may be coupled with contacts (e.g., the S/D contacts 3124) of the device layer 3104. The vias 3128b of the first interconnect layer 3106 may be coupled with the lines 3128a of a second interconnect layer 3108.

The second interconnect layer 3108 (referred to as Metal 2 or “M2”) may be formed directly on the first interconnect layer 3106. In some embodiments, the second interconnect layer 3108 may include via 3128b to couple the lines 3128 of the second interconnect layer 3108 with the lines 3128a of a third interconnect layer 3110. Although the lines 3128a and the vias 3128b are structurally delineated with a line within individual interconnect layers for the sake of clarity, the lines 3128a and the vias 3128b may be structurally and/or materially contiguous (e.g., simultaneously filled during a dual-damascene process) in some embodiments.

The third interconnect layer 3110 (referred to as Metal 3 or “M3”) (and additional interconnect layers, as desired) may be formed in succession on the second interconnect layer 3108 according to similar techniques and configurations described in connection with the second interconnect layer 3108 or the first interconnect layer 3106. In some embodiments, the interconnect layers that are “higher up” in the metallization stack 3119 in the integrated circuit device 3100 (i.e., farther away from the device layer 3104) may be thicker that the interconnect layers that are lower in the metallization stack 3119, with lines 3128a and vias 3128b in the higher interconnect layers being thicker than those in the lower interconnect layers.

The integrated circuit device 3100 may include a solder resist material 3134 (e.g., polyimide or similar material) and one or more conductive contacts 3136 formed on the interconnect layers 3106-3110. In FIG. 31, the conductive contacts 3136 are illustrated as taking the form of bond pads. The conductive contacts 3136 may be electrically coupled with the interconnect structures 3128 and configured to route the electrical signals of the transistor(s) 3140 to external devices. For example, solder bonds may be formed on the one or more conductive contacts 3136 to mechanically and/or electrically couple an integrated circuit die including the integrated circuit device 3100 with another component (e.g., a printed circuit board). The integrated circuit device 3100 may include additional or alternate structures to route the electrical signals from the interconnect layers 3106-3110; for example, the conductive contacts 3136 may include other analogous features (e.g., posts) that route the electrical signals to external components.

In some embodiments in which the integrated circuit device 3100 is a double-sided die, the integrated circuit device 3100 may include another metallization stack (not shown) on the opposite side of the device layer(s) 3104. This metallization stack may include multiple interconnect layers as discussed above with reference to the interconnect layers 3106-3110, to provide conductive pathways (e.g., including conductive lines and vias) between the device layer(s) 3104 and additional conductive contacts (not shown) on the opposite side of the integrated circuit device 3100 from the conductive contacts 3136.

In other embodiments in which the integrated circuit device 3100 is a double-sided die, the integrated circuit device 3100 may include one or more through silicon vias (TSVs) through the die substrate 3102; these TSVs may make contact with the device layer(s) 3104, and may provide conductive pathways between the device layer(s) 3104 and additional conductive contacts (not shown) on the opposite side of the integrated circuit device 3100 from the conductive contacts 3136. In some embodiments, TSVs extending through the substrate can be used for routing power and ground signals from conductive contacts on the opposite side of the integrated circuit device 3100 from the conductive contacts 3136 to the transistors 3140 and any other components integrated into the die 3100, and the metallization stack 3119 can be used to route I/O signals from the conductive contacts 3136 to transistors 3140 and any other components integrated into the die 3100.

Multiple integrated circuit devices 3100 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

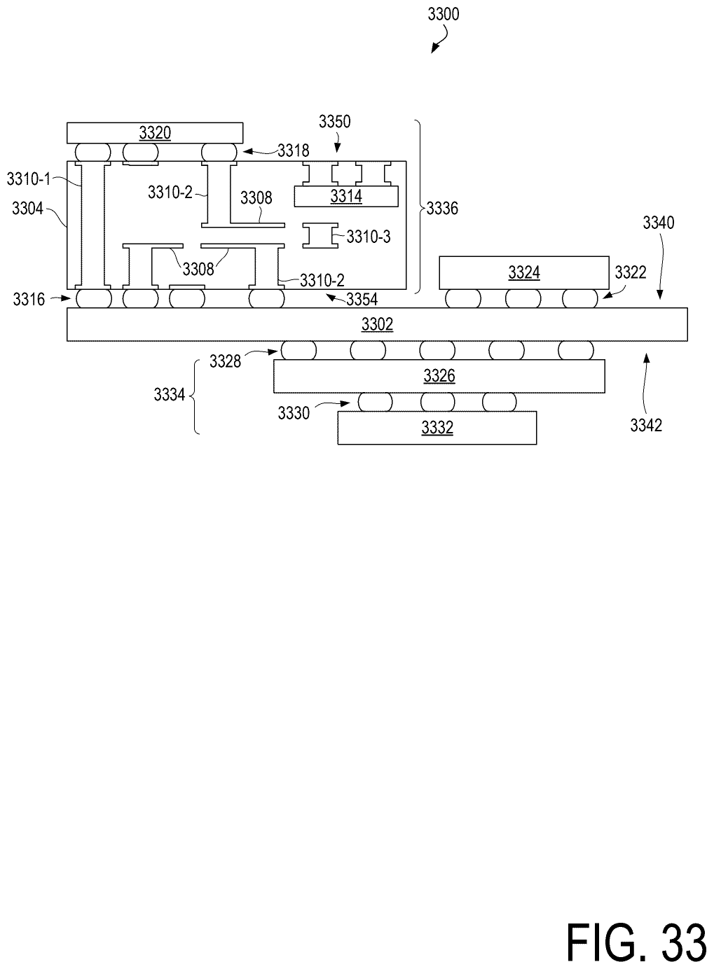

FIG. 33 is a cross-sectional side view of an integrated circuit device assembly 3300 that may include any of the integrated circuit components 100, 2300, 2400, 2500, 2600, 2700, 2800, 2900 disclosed herein. In some embodiments, the integrated circuit device assembly 3300 may be a integrated circuit components 100, 2300, 2400, 2500, 2600, 2700, 2800, 2900. The integrated circuit device assembly 3300 includes a number of components disposed on a circuit board 3302 (which may be a motherboard, system board, mainboard, etc.). The integrated circuit device assembly 3300 includes components disposed on a first face 3340 of the circuit board 3302 and an opposing second face 3342 of the circuit board 3302; generally, components may be disposed on one or both faces 3340 and 3342. Any of the integrated circuit components discussed below with reference to the integrated circuit device assembly 3300 may take the form of any suitable ones of the embodiments of the integrated circuit components 100, 2300, 2400, 2500, 2600, 2700, 2800, 2900 disclosed herein.

In some embodiments, the circuit board 3302 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 3302. In other embodiments, the circuit board 3302 may be a non-PCB substrate. In some embodiments the circuit board 3302 may be, for example, the circuit board 102. The integrated circuit device assembly 3300 illustrated in FIG. 33 includes a package-on-interposer structure 3336 coupled to the first face 3340 of the circuit board 3302 by coupling components 3316. The coupling components 3316 may electrically and mechanically couple the package-on-interposer structure 3336 to the circuit board 3302, and may include solder balls (as shown in FIG. 33), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 3336 may include an integrated circuit component 3320 coupled to an interposer 3304 by coupling components 3318. The coupling components 3318 may take any suitable form for the application, such as the forms discussed above with reference to the coupling components 3316. Although a single integrated circuit component 3320 is shown in FIG. 33, multiple integrated circuit components may be coupled to the interposer 3304; indeed, additional interposers may be coupled to the interposer 3304. The interposer 3304 may provide an intervening substrate used to bridge the circuit board 3302 and the integrated circuit component 3320.

The integrated circuit component 3320 may be a packaged or unpacked integrated circuit product that includes one or more integrated circuit dies (e.g., the die 3002 of FIG. 30, the integrated circuit device 3100 of FIG. 31) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 3320, a single monolithic integrated circuit die comprises solder bumps attached to contacts on the die. The solder bumps allow the die to be directly attached to the interposer 3304. The integrated circuit component 3320 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 3320 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 3320 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 3320 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 3304 may spread connections to a wider pitch or reroute a connection to a different connection. For example, the interposer 3304 may couple the integrated circuit component 3320 to a set of ball grid array (BGA) conductive contacts of the coupling components 3316 for coupling to the circuit board 3302. In the embodiment illustrated in FIG. 33, the integrated circuit component 3320 and the circuit board 3302 are attached to opposing sides of the interposer 3304; in other embodiments, the integrated circuit component 3320 and the circuit board 3302 may be attached to a same side of the interposer 3304. In some embodiments, three or more components may be interconnected by way of the interposer 3304.

In some embodiments, the interposer 3304 may be formed as a PCB, including multiple metal layers separated from one another by layers of dielectric material and interconnected by electrically conductive vias. In some embodiments, the interposer 3304 may be formed of an epoxy resin, a fiberglass-reinforced epoxy resin, an epoxy resin with inorganic fillers, a ceramic material, or a polymer material such as polyimide. In some embodiments, the interposer 3304 may be formed of alternate rigid or flexible materials that may include the same materials described above for use in a semiconductor substrate, such as silicon, germanium, and other group III-V and group IV materials. The interposer 3304 may include metal interconnects 3308 and vias 3310, including but not limited to through hole vias 3310-1 (that extend from a first face 3350 of the interposer 3304 to a second face 3354 of the interposer 3304), blind vias 3310-2 (that extend from the first or second faces 3350 or 3354 of the interposer 3304 to an internal metal layer), and buried vias 3310-3 (that connect internal metal layers).

In some embodiments, the interposer 3304 can comprise a silicon interposer. Through silicon vias (TSV) extending through the silicon interposer can connect connections on a first face of a silicon interposer to an opposing second face of the silicon interposer. In some embodiments, an interposer 3304 comprising a silicon interposer can further comprise one or more routing layers to route connections on a first face of the interposer 3304 to an opposing second face of the interposer 3304.

The interposer 3304 may further include embedded devices 3314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 3304. The package-on-interposer structure 3336 may take the form of any of the package-on-interposer structures known in the art.

The integrated circuit device assembly 3300 may include an integrated circuit component 3324 coupled to the first face 3340 of the circuit board 3302 by coupling components 3322. The coupling components 3322 may take the form of any of the embodiments discussed above with reference to the coupling components 3316, and the integrated circuit component 3324 may take the form of any of the embodiments discussed above with reference to the integrated circuit component 3320.

The integrated circuit device assembly 3300 illustrated in FIG. 33 includes a package-on-package structure 3334 coupled to the second face 3342 of the circuit board 3302 by coupling components 3328. The package-on-package structure 3334 may include an integrated circuit component 3326 and an integrated circuit component 3332 coupled together by coupling components 3330 such that the integrated circuit component 3326 is disposed between the circuit board 3302 and the integrated circuit component 3332. The coupling components 3328 and 3330 may take the form of any of the embodiments of the coupling components 3316 discussed above, and the integrated circuit components 3326 and 3332 may take the form of any of the embodiments of the integrated circuit component 3320 discussed above. The package-on-package structure 3334 may be configured in accordance with any of the package-on-package structures known in the art.

FIG. 34 is a block diagram of an example electrical device 3400 that may include one or more of the integrated circuit components 100, 2300, 2400, 2500, 2600, 2700, 2800, 2900 disclosed herein. For example, any suitable ones of the components of the electrical device 3400 may include one or more of the integrated circuit device assemblies 3300, integrated circuit components 3320, integrated circuit devices 3100, or integrated circuit dies 3002 disclosed herein, and may be arranged in any of the integrated circuit components 100, 2300, 2400, 2500, 2600, 2700, 2800, 2900 disclosed herein. A number of components are illustrated in FIG. 34 as included in the electrical device 3400, but any one or more of these components may be omitted or duplicated, as suitable for the application. In some embodiments, some or all of the components included in the electrical device 3400 may be attached to one or more motherboards mainboards, or system boards. In some embodiments, one or more of these components are fabricated onto a single system-on-a-chip (SoC) die.

Additionally, in various embodiments, the electrical device 3400 may not include one or more of the components illustrated in FIG. 34, but the electrical device 3400 may include interface circuitry for coupling to the one or more components. For example, the electrical device 3400 may not include a display device 3406, but may include display device interface circuitry (e.g., a connector and driver circuitry) to which a display device 3406 may be coupled. In another set of examples, the electrical device 3400 may not include an audio input device 3424 or an audio output device 3408, but may include audio input or output device interface circuitry (e.g., connectors and supporting circuitry) to which an audio input device 3424 or audio output device 3408 may be coupled.

The electrical device 3400 may include one or more processor units 3402 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 3402 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 3400 may include a memory 3404, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 3404 may include memory that is located on the same integrated circuit die as the processor unit 3402. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 3400 can comprise one or more processor units 3402 that are heterogeneous or asymmetric to another processor unit 3402 in the electrical device 3400. There can be a variety of differences between the processing units 3402 in a system in terms of a spectrum of metrics of merit including architectural, microarchitectural, thermal, power consumption characteristics, and the like. These differences can effectively manifest themselves as asymmetry and heterogeneity among the processor units 3402 in the electrical device 3400.

In some embodiments, the electrical device 3400 may include a communication component 3412 (e.g., one or more communication components). For example, the communication component 3412 can manage wireless communications for the transfer of data to and from the electrical device 3400. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 3412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 3412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 3412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 3412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 3412 may operate in accordance with other wireless protocols in other embodiments. The electrical device 3400 may include an antenna 3422 to facilitate wireless communications and/or to receive other wireless communications (such as AM or FM radio transmissions).

In some embodiments, the communication component 3412 may manage wired communications, such as electrical, optical, or any other suitable communication protocols (e.g., IEEE 802.3 Ethernet standards). As noted above, the communication component 3412 may include multiple communication components. For instance, a first communication component 3412 may be dedicated to shorter-range wireless communications such as Wi-Fi or Bluetooth, and a second communication component 3412 may be dedicated to longer-range wireless communications such as global positioning system (GPS), EDGE, GPRS, CDMA, WiMAX, LTE, EV-DO, or others. In some embodiments, a first communication component 3412 may be dedicated to wireless communications, and a second communication component 3412 may be dedicated to wired communications.

The electrical device 3400 may include battery/power circuitry 3414. The battery/power circuitry 3414 may include one or more energy storage devices (e.g., batteries or capacitors) and/or circuitry for coupling components of the electrical device 3400 to an energy source separate from the electrical device 3400 (e.g., AC line power).

The electrical device 3400 may include a display device 3406 (or corresponding interface circuitry, as discussed above). The display device 3406 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 3400 may include an audio output device 3408 (or corresponding interface circuitry, as discussed above). The audio output device 3408 may include any embedded or wired or wirelessly connected external device that generates an audible indicator, such as speakers, headsets, or earbuds.

The electrical device 3400 may include an audio input device 3424 (or corresponding interface circuitry, as discussed above). The audio input device 3424 may include any embedded or wired or wirelessly connected device that generates a signal representative of a sound, such as microphones, microphone arrays, or digital instruments (e.g., instruments having a musical instrument digital interface (MIDI) output). The electrical device 3400 may include a Global Navigation Satellite System (GNSS) device 3418 (or corresponding interface circuitry, as discussed above), such as a Global Positioning System (GPS) device. The GNSS device 3418 may be in communication with a satellite-based system and may determine a geolocation of the electrical device 3400 based on information received from one or more GNSS satellites, as known in the art.

The electrical device 3400 may include an other output device 3410 (or corresponding interface circuitry, as discussed above). Examples of the other output device 3410 may include an audio codec, a video codec, a printer, a wired or wireless transmitter for providing information to other devices, or an additional storage device.

The electrical device 3400 may include an other input device 3420 (or corresponding interface circuitry, as discussed above). Examples of the other input device 3420 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 3400 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 3400 may be any other electronic device that processes data. In some embodiments, the electrical device 3400 may comprise multiple discrete physical components. Given the range of devices that the electrical device 3400 can be manifested as in various embodiments, in some embodiments, the electrical device 3400 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising a substrate core, wherein a cavity is defined in the substrate core; a first die disposed in the cavity, the first die comprising a capacitor; and a second die disposed in the cavity, the second die comprising a capacitor, wherein the second die is disposed above the first die.

Example 2 includes the subject matter of Example 1, and wherein the first die is a deep trench capacitor die, wherein the second die is a deep trench capacitor die.

Example 3 includes the subject matter of any of Examples 1 and 2, and wherein the first die comprises a plurality of trenches, wherein individual trenches of the plurality of trenches extend from a surface of the first die to at least 10 micrometers below the surface of the first die.

Example 4 includes the subject matter of any of Examples 1-3, and wherein the first die is a deep trench capacitor die, wherein the second die comprises a magnetic inductor array.

Example 5 includes the subject matter of any of Examples 1-4, and wherein a bottom surface of the first die is within 100 micrometers of a plane defined by a bottom surface of the substrate core, wherein a top surface of the second die is within 100 micrometers of a plane defined by a top surface of the substrate core.

Example 6 includes the subject matter of any of Examples 1-5, and wherein the substrate core has a thickness of at least 800 micrometers.

Example 7 includes the subject matter of any of Examples 1-6, and wherein a difference between a thickness of the first die and a thickness of the second die is less than five micrometers.

Example 8 includes the subject matter of any of Examples 1-7, and wherein a difference between a thickness of the first die and a thickness of the second die is at least 20 micrometers.

Example 9 includes the subject matter of any of Examples 1-8, and wherein the substrate core has a thickness less than 200 micrometers.

Example 10 includes the subject matter of any of Examples 1-9, and further including a third die disposed on a surface of circuit board of the apparatus, wherein the third die is positioned at least partially above the first die and the second die.

Example 11 includes the subject matter of any of Examples 1-10, and further including a fourth semiconductor die disposed on a second surface of the circuit board, the second surface opposite the surface, wherein the fourth semiconductor die is positioned at least partially below the first die and the second die.

Example 12 includes the subject matter of any of Examples 1-11, and further including a fully-integrated voltage regulator (FIVR), wherein the FIVR comprises the first die and the second die.

Example 13 includes the subject matter of any of Examples 1-12, and further including a third power component, wherein the third power component is disposed above the first die and next to the second die.

Example 14 includes the subject matter of any of Examples 1-13, and further including a third power component disposed in the cavity; and a fourth power component disposed in the cavity, wherein the fourth power component is disposed above the third power component.

Example 15 includes the subject matter of any of Examples 1-14, and wherein a second cavity is defined in the substrate core, the second cavity separate from the cavity, further comprising a third power component disposed in the second cavity; and a fourth power component disposed in the second cavity, wherein the fourth power component is disposed above the third power component.

Example 16 includes the subject matter of any of Examples 1-15, and further including a plurality of build-up layers adjacent the substrate core.

Example 17 includes an apparatus comprising a substrate core comprising a top surface and a bottom surface, wherein a cavity is defined in the substrate core, wherein the cavity extends from the top surface of the substrate core to the bottom surface of the substrate core; a power component stack disposed in the cavity, wherein the power component stack extends at least from a top plane defined by the top surface of the substrate core to a bottom plane defined by the bottom surface of the substrate core, wherein the power component stack comprises a first power component and a second power component.

Example 18 includes the subject matter of Example 17, and wherein the first power component is a deep trench capacitor, wherein the second power component is a deep trench capacitor.

Example 19 includes the subject matter of any of Examples 17 and 18, and wherein the first power component comprises a semiconductor die, wherein the semiconductor die comprises a plurality of trenches, wherein individual trenches of the plurality of trenches extend from a surface of the semiconductor die to at least 10 micrometers below the surface of the semiconductor die.

Example 20 includes the subject matter of any of Examples 17-19, and wherein the first power component is a deep trench capacitor, wherein the second power component is a magnetic inductor array.

Example 21 includes the subject matter of any of Examples 17-20, and wherein a bottom surface of the first power component is within 100 micrometers of a plane defined by a bottom surface of the substrate core, wherein a top surface of the second power component is within 100 micrometers of a plane defined by the top surface of the substrate core.

Example 22 includes the subject matter of any of Examples 17-21, and wherein the substrate core has a thickness of at least 800 micrometers.

Example 23 includes the subject matter of any of Examples 17-22, and wherein a difference between a thickness of the first power component and a thickness of the second power component is less than five micrometers.

Example 24 includes the subject matter of any of Examples 17-23, and wherein a difference between a thickness of the first power component and a thickness of the second power component is at least 20 micrometers.

Example 25 includes the subject matter of any of Examples 17-24, and wherein the substrate core has a thickness less than 200 micrometers.

Example 26 includes the subject matter of any of Examples 17-25, and further including a semiconductor die disposed on a surface of a circuit board of the apparatus, wherein the semiconductor die is positioned at least partially above the first power component and the second power component.

Example 27 includes the subject matter of any of Examples 17-26, and further including a second semiconductor die disposed on a second surface of the circuit board, the second surface opposite the surface, wherein the second semiconductor die is positioned at least partially below the first power component and the second power component.

Example 28 includes the subject matter of any of Examples 17-27, and further including a fully-integrated voltage regulator (FIVR), wherein the FIVR comprises the first power component and the second power component.

Example 29 includes the subject matter of any of Examples 17-28, and further including a third power component, wherein the third power component is disposed above the first power component and next to the second power component.

Example 30 includes the subject matter of any of Examples 17-29, and further including a third power component disposed in the cavity; and a fourth power component disposed in the cavity, wherein the fourth power component is disposed above the third power component.

Example 31 includes the subject matter of any of Examples 17-30, and wherein a second cavity is defined in the substrate core, the second cavity separate from the cavity, further comprising a third power component disposed in the second cavity; and a fourth power component disposed in the second cavity, wherein the fourth power component is disposed above the third power component.

Example 32 includes the subject matter of any of Examples 17-31, and further including a plurality of build-up layers adjacent the substrate core.

Example 33 includes an apparatus comprising a circuit board; a semiconductor die; and a power component stack disposed in the circuit board, wherein the power component stack is to provide power to the semiconductor die, wherein the power component stack comprises a first power component and a second power component.

Example 34 includes the subject matter of Example 33, and wherein the first power component is a deep trench capacitor, wherein the second power component is a deep trench capacitor.

Example 35 includes the subject matter of any of Examples 33 and 34, and wherein the first power component comprises a semiconductor die, wherein the semiconductor die comprises a plurality of trenches, wherein individual trenches of the plurality of trenches extend from a surface of the semiconductor die to at least 10 micrometers below the surface of the semiconductor die.

Example 36 includes the subject matter of any of Examples 33-35, and wherein the first power component is a deep trench capacitor, wherein the second power component is a magnetic inductor array.

Example 37 includes the subject matter of any of Examples 33-36, and wherein a bottom surface of the first power component is within 100 micrometers of a plane defined by a bottom surface of a substrate core of the circuit board, wherein a top surface of the second power component is within 100 micrometers of a plane defined by a top surface of the substrate core.

Example 38 includes the subject matter of any of Examples 33-37, and wherein a substrate core of the circuit board has a thickness of at least 800 micrometers.

Example 39 includes the subject matter of any of Examples 33-38, and wherein a difference between a thickness of the first power component and a thickness of the second power component is less than five micrometers.

Example 40 includes the subject matter of any of Examples 33-39, and wherein a difference between a thickness of the first power component and a thickness of the second power component is at least 20 micrometers.

Example 41 includes the subject matter of any of Examples 33-40, and wherein a substrate core of the circuit board has a thickness less than 200 micrometers.

Example 42 includes the subject matter of any of Examples 33-41, and wherein the semiconductor die is positioned at least partially above the first power component and the second power component.

Example 43 includes the subject matter of any of Examples 33-42, and further including a second semiconductor die disposed on a second surface of the circuit board, the second surface opposite the surface, wherein the second semiconductor die is positioned at least partially below the first power component and the second power component.

Example 44 includes the subject matter of any of Examples 33-43, and further including a fully-integrated voltage regulator (FIVR), wherein the FIVR comprises the first power component and the second power component.

Example 45 includes the subject matter of any of Examples 33-44, and further including a third power component, wherein the third power component is disposed above the first power component and next to the second power component.

Example 46 includes the subject matter of any of Examples 33-45, and wherein a cavity is defined in a substrate core of the circuit board, wherein the first power component and the second power component are disposed in the cavity, further comprising a third power component disposed in the cavity; and a fourth power component disposed in the cavity, wherein the fourth power component is disposed above the third power component.

Example 47 includes the subject matter of any of Examples 33-46, and wherein a cavity is defined in a substrate core of the circuit board, wherein the first power component and the second power component are disposed in the cavity, wherein a second cavity is defined in a substrate core of the circuit board, the second cavity separate from the cavity, further comprising a third power component disposed in the second cavity; and a fourth power component disposed in the second cavity, wherein the fourth power component is disposed above the third power component.

Example 48 includes the subject matter of any of Examples 33-47, and wherein the circuit board comprises a substrate core and a plurality of build-up layers adjacent the substrate core.

Example 49 includes an apparatus comprising a substrate core, wherein a cavity is defined in the substrate core; a stacked means for providing power, wherein the stacked means for providing power is disposed within the substrate core.

Example 50 includes the subject matter of Example 49, and wherein the stacked means for providing power comprises one or more deep trench capacitors.

Example 51 includes the subject matter of any of Examples 49 and 50, and wherein the stacked means for providing power comprises a semiconductor die, wherein the semiconductor die comprises a plurality of trenches, wherein individual trenches of the plurality of trenches extend from a surface of the semiconductor die to at least 10 micrometers below the surface of the semiconductor die.

Example 52 includes the subject matter of any of Examples 49-51, and wherein the stacked means for providing power comprises a deep trench capacitor and a magnetic inductor array.

Example 53 includes the subject matter of any of Examples 49-52, and wherein a bottom surface of the stacked means for providing power is within 100 micrometers of a plane defined by a bottom surface of the substrate core, wherein a top surface of the stacked means for providing power is within 100 micrometers of a plane defined by a top surface of the substrate core.

Example 54 includes the subject matter of any of Examples 49-53, and wherein the substrate core has a thickness of at least 800 micrometers.

Example 55 includes the subject matter of any of Examples 49-54, and wherein the substrate core has a thickness less than 200 micrometers.

Example 56 includes the subject matter of any of Examples 49-55, and further including a semiconductor die disposed on a surface of a circuit board of the apparatus, wherein the semiconductor die is positioned at least partially above the stacked means for providing power.

Example 57 includes the subject matter of any of Examples 49-56, and further including a second semiconductor die disposed on a second surface of the circuit board, the second surface opposite the surface, wherein the second semiconductor die is positioned at least partially below the stacked means for providing power.

Example 58 includes the subject matter of any of Examples 49-57, and further including a fully-integrated voltage regulator (FIVR), wherein the FIVR comprises the stacked means for providing power.

Example 59 includes the subject matter of any of Examples 49-58, and further including a plurality of build-up layers adjacent the substrate core.

Example 60 includes a method comprising forming a cavity in a substrate core; disposing a first power component and a second power component in the cavity, wherein the second power component is disposed above the first power component; and filling the cavity with a filler material.

Example 61 includes the subject matter of Example 60, and further including forming a plurality of power components on a semiconductor wafer; thinning the semiconductor wafer; and dicing the semiconductor wafer to form the first power component.

Example 62 includes the subject matter of any of Examples 60 and 61, and further including forming a plurality of power components on a semiconductor wafer; dicing the semiconductor wafer to form the first power component; and thinning the first power component after dicing of the semiconductor wafer and before disposing the first power component in the cavity.

Example 63 includes the subject matter of any of Examples 60-62, and wherein disposing the first power component and the second power component in the cavity comprises disposing the first power component in the cavity; depositing die attach film on the first power component in the cavity; and disposing the second power component on the die attach film.

Example 64 includes the subject matter of any of Examples 60-63, and further including forming a first plurality of power components on a first semiconductor wafer; forming second plurality of power components on a second semiconductor wafer; bonding the first semiconductor wafer and the second semiconductor wafer, wherein bonding the first semiconductor wafer and the second semiconductor wafer comprising bonding the first power component and the second power component; and dicing the first semiconductor wafer and the second semiconductor wafer, wherein disposing the first power component and the second power component in the cavity comprises disposing the first power component and the second power component in the cavity while the first power component is bonded to the second power component.

Example 65 includes the subject matter of any of Examples 60-64, and wherein disposing the first power component and the second power component in the cavity comprises bonding the first power component and the second power component; and disposing the first power component and the second power component in the cavity while the first power component is bonded to the second power component.

Example 66 includes the subject matter of any of Examples 60-65, and wherein the first power component is a deep trench capacitor, wherein the second power component is a deep trench capacitor.

Example 67 includes the subject matter of any of Examples 60-66, and wherein the first power component comprises a semiconductor die, wherein the semiconductor die comprises a plurality of trenches, wherein individual trenches of the plurality of trenches extend from a surface of the semiconductor die to at least 10 micrometers below the surface of the semiconductor die.

Example 68 includes the subject matter of any of Examples 60-67, and wherein the first power component is a deep trench capacitor, wherein the second power component is a magnetic inductor array.

Example 69 includes the subject matter of any of Examples 60-68, and wherein a bottom surface of the first power component is within 100 micrometers of a plane defined by a bottom surface of the substrate core, wherein a top surface of the second power component is within 100 micrometers of a plane defined by a top surface of the substrate core.

Example 70 includes the subject matter of any of Examples 60-69, and wherein the substrate core has a thickness of at least 800 micrometers.

Example 71 includes the subject matter of any of Examples 60-70, and wherein a difference between a thickness of the first power component and a thickness of the second power component is less than five micrometers.

Example 72 includes the subject matter of any of Examples 60-71, and wherein a difference between a thickness of the first power component and a thickness of the second power component is at least 20 micrometers.

Example 73 includes the subject matter of any of Examples 60-72, and wherein the substrate core has a thickness less than 200 micrometers.

Example 74 includes the subject matter of any of Examples 60-73, and further including disposing a semiconductor die on a surface of a circuit board comprising the substrate core, wherein the semiconductor die is positioned at least partially above the first power component and the second power component.

Example 75 includes the subject matter of any of Examples 60-74, and further including disposing a second semiconductor die on a second surface of the circuit board, the second surface opposite the surface, wherein the second semiconductor die is positioned at least partially below the first power component and the second power component.

Example 76 includes the subject matter of any of Examples 60-75, and wherein an integrated circuit component comprising the circuit board and the semiconductor die further comprise a fully-integrated voltage regulator (FIVR), wherein the FIVR comprises the first power component and the second power component.

Example 77 includes the subject matter of any of Examples 60-76, and further including disposing a third power component above the first power component and next to the second power component.

Example 78 includes the subject matter of any of Examples 60-77, and further including disposing a third power component in the cavity; and disposing a fourth power component in the cavity, wherein the fourth power component is disposed above the third power component.

Example 79 includes the subject matter of any of Examples 60-78, and further including forming a second cavity in the substrate core, the second cavity separate from the cavity; disposing a third power component in the second cavity; and disposing a fourth power component in the second cavity, wherein the fourth power component is disposed above the third power component.

Example 80 includes the subject matter of any of Examples 60-79, and further including forming a plurality of build-up layers adjacent the substrate core.

1. An apparatus comprising:
a substrate core, wherein a cavity is defined in the substrate core;
a first die disposed in the cavity, the first die comprising a capacitor; and
a second die disposed in the cavity, the second die comprising a capacitor, wherein the second die is disposed above the first die.

2. The apparatus of claim 1, wherein the first die is a deep trench capacitor die, wherein the second die is a deep trench capacitor die.

3. The apparatus of claim 1, wherein the first die is a deep trench capacitor die, wherein the second die comprises a magnetic inductor array.

4. The apparatus of claim 1, wherein a bottom surface of the first die is within 100 micrometers of a plane defined by a bottom surface of the substrate core, wherein a top surface of the second die is within 100 micrometers of a plane defined by a top surface of the substrate core.

5. The apparatus of claim 1, wherein the substrate core has a thickness of at least 800 micrometers.

6. The apparatus of claim 1, wherein a difference between a thickness of the first die and a thickness of the second die is less than five micrometers.

7. The apparatus of claim 1, wherein a difference between a thickness of the first die and a thickness of the second die is at least 20 micrometers.

8. An integrated circuit component comprising the apparatus of claim 1, further comprising a third die disposed on a surface of a circuit board of the apparatus, wherein the third die is positioned at least partially above the first die and the second die.

9. The integrated circuit component of claim 8, further comprising a fully-integrated voltage regulator (FIVR), wherein the FIVR comprises the first die and the second die.

10. An apparatus comprising:
a circuit board;
a semiconductor die; and
a power component stack disposed in the circuit board, wherein the power component stack is to provide power to the semiconductor die, wherein the power component stack comprises a first power component and a second power component.

11. The apparatus of claim 10, wherein the first power component is a deep trench capacitor, wherein the second power component is a deep trench capacitor.

12. The apparatus of claim 10, wherein a substrate core of the circuit board has a thickness of at least 800 micrometers.

13. The apparatus of claim 10, further comprising a third power component, wherein the third power component is disposed above the first power component and next to the second power component.

14. The apparatus of claim 10, wherein a cavity is defined in a substrate core of the circuit board, wherein the first power component and the second power component are disposed in the cavity, further comprising:
a third power component disposed in the cavity; and
a fourth power component disposed in the cavity, wherein the fourth power component is disposed above the third power component.

15. The apparatus of claim 10, wherein a cavity is defined in a substrate core of the circuit board, wherein the first power component and the second power component are disposed in the cavity, wherein a second cavity is defined in a substrate core of the circuit board, the second cavity separate from the cavity, further comprising:
a third power component disposed in the second cavity; and
a fourth power component disposed in the second cavity, wherein the fourth power component is disposed above the third power component.

16. The apparatus of claim 10, wherein the circuit board comprises a substrate core and a plurality of build-up layers adjacent the substrate core.

17. A method comprising:
forming a cavity in a substrate core;
disposing a first power component and a second power component in the cavity, wherein the second power component is disposed above the first power component; and
filling the cavity with a filler material.

18. The method of claim 17, further comprising:
forming a plurality of power components on a semiconductor wafer;
thinning the semiconductor wafer; and
dicing the thinned semiconductor wafer to form the first power component.

19. The method of claim 17, further comprising:
forming a plurality of power components on a semiconductor wafer;
dicing the semiconductor wafer to form the first power component; and
thinning the first power component after dicing of the semiconductor wafer and before disposing the first power component in the cavity.

20. The method of claim 17, further comprising:
forming a first plurality of power components on a first semiconductor wafer;
forming second plurality of power components on a second semiconductor wafer;
bonding the first semiconductor wafer and the second semiconductor wafer, wherein bonding the first semiconductor wafer and the second semiconductor wafer comprising bonding the first power component and the second power component; and
dicing the first semiconductor wafer and the second semiconductor wafer,
wherein disposing the first power component and the second power component in the cavity comprises disposing the first power component and the second power component in the cavity while the first power component is bonded to the second power component.
